(19) United States
(12) Patent Application Publication
(10) Pub. No.: US 2026/0271548 A1
(43) Pub. Date: Sep. 10, 2026

(54) DISPLAY DEVICE INCLUDING GATE DRIVER WITH BUFFER TRANSISTOR AND ELECTRONIC DEVICE INCLUDING THE SAME

(71) Applicant: SAMSUNG DISPLAY CO., LTD., YONGIN-SI (KR)

(72) Inventor: EOK SU KIM, Yongin-si (KR)

(21) Appl. No.: 19/379,102

(22) Filed: Nov. 4, 2025

(30) Foreign Application Priority Data
Mar. 7, 2025 (KR) 10-2025-0029677

(51) Int. Cl. H10K 59/123; H10K 59/121

(52) U.S. Cl. CPC H10K 59/123; H10K 59/1213

(57) ABSTRACT

A display device includes a gate driver which is disposed in a peripheral area that surrounds a display area that includes pixels. The gate driver provides a gate signal to the pixels, and includes a buffer transistor including an active layer with conductive regions and a channel region, a gate insulating layer with opening areas, and a gate electrode that overlaps the channel region. First and second connection patterns extend through the openings to electrically connect the active layer to bottom metal layers, while a third connection pattern ties to the conductive regions and outputs a gate signal.

### CROSS-REFERENCE TO RELATED APPLICATION

This application claims priority under 35 U.S.C. § 119 to Korean Patent Application No. 10-2025-0029677, filed on Mar. 7, 2025 in the Korean Intellectual Property Office (KIPO), the entire contents of which are hereby incorporated by reference.

### TECHNICAL FIELD

The present disclosure relates to a display device and, more specifically, to a display device including a gate driver with a buffer transistor and an electronic device including the same.

### DISCUSSION OF THE RELATED ART

Display devices have become an increasingly indispensable component of modern technology. Accordingly, the use of display devices such as a liquid crystal display (LCD) device, an organic light emitting diode (OLED) display device, a plasma display device, and the like is increasing.

A display device may include a display area which displays an image and a peripheral area surrounding the display area. While this peripheral area may include important components, from the perspective of a viewer, this area may appear as dead space as no image is displayed thereon. Thus, it may be desirable to reduce the size of this peripheral area while enlarging the size of the display area.

### SUMMARY

A display device includes a substrate including a display area including a plurality of pixels and a peripheral area surrounding the display area. A gate driver is disposed in the peripheral area and is configured to provide a gate signal to the plurality of pixels. and the gate driver includes at least one buffer transistor including a first lower metal layer disposed on the substrate, a second lower metal layer disposed on a same layer as the first lower metal layer, an active layer disposed on the first and second lower metal layers and including a plurality of active patterns that are spaced apart from each other along a first direction, a gate electrode disposed on the active layer and overlapping a channel region of the active layer, a first connection electrode contacting the first lower metal layer and a first conductive region of the active layer and including a plurality of first connection patterns spaced apart from each other along the first direction, and a second connection electrode contacting the second lower metal layer and a second conductive region of the active layer and including a plurality of second connection patterns spaced apart from each other along the first direction.

Each of the first connection patterns may contact the first lower metal layer through a separation space between two adjacent active patters among the active patterns, and each of the second connection patterns may contact the second lower metal layer through the separation space.

A plurality of first holes penetrating a portion of the first conductive region and spaced apart from each other and a plurality of second holes penetrating a portion of the second conductive region and spaced apart from each other may be defined in each of the active patterns. In one active pattern, among the active patterns, the first holes and the second holes may be alternatively arranged along a second direction intersecting the first direction.

Each of the first holes may be located between the first connection patterns and each of the second holes may be located between the second connection patterns.

The display device may further include a gate insulating layer disposed between the active layer and the gate electrode, the gate insulating layer including a first opening area exposing the first holes and the first conductive region, and a second opening area exposing the second holes and the second conductive region. Opposite ends, in the first direction, of the first opening area may overlap the first connection patterns and opposite ends, in the first direction, of the second opening area may overlap the second connection patterns.

The first opening area may extend continuously in the first direction and the second opening area may extended in the first direction.

The opposite ends, in the first direction, of the first opening area may coincide with opposite ends, in the first direction, of each of the first holes. The opposite ends, in the first direction, of the second opening area may coincide with opposite ends, in the first direction, of each of the second holes.

The first opening area may be divided into a plurality of first sub-opening areas spaced apart from each other along the first direction and the second opening area may be divided into a plurality of second sub-opening areas spaced apart from each other along the first direction.

One end of each of the first sub-opening areas, in a second direction interesting the first direction, may overlap a separation space between two adjacent active patterns among the active patterns, and one end of each of the second opening areas, in the second direction, may overlap the separation space.

The gate electrode may include a plurality of electrode branch portions, each extending along the first direction and spaced apart from each other along a second direction intersecting the first direction, and the first lower metal layer may include a plurality of metal branch portions each extending along the first direction and spaced apart from each other along the second direction.

The second lower metal layer may include a plurality of metal patterns, each extending along the first direction and spaced apart from each other along the second direction, one of the lower metal patterns may be disposed between the metal branch portions, and each of the electrode branch portions may be disposed between one metal branch portion among the metal branch portions and one lower metal pattern adjacent to the one metal branch portion among the lower metal patterns.

The first connection patterns may contact the metal branch portions, respectively and the second connection patterns may contact the lower metal patterns, respectively.

The buffer transistor may further include a third connection pattern which contacts one end of the second lower metal layer, the first conductive region, and the second conductive region, and is configured to provide the gate signal.

The active layer may include a metal oxide semiconductor.

The first connection electrode and the second connection electrode may include a same material as the gate electrode.

An electronic device includes a display device including a substrate including a display area including a plurality of pixels and a peripheral area surrounding the display area. A gate driver is disposed in the peripheral area and is configured to provide a gate signal to the plurality of pixels. and the gate driver includes at least one buffer transistor including a first lower metal layer disposed on the substrate, a second lower metal layer disposed on a same layer as the first lower metal layer, an active layer disposed on the first and second lower metal layers and including a plurality of active patterns spaced apart from each other along a first direction, a gate electrode disposed on the active layer and overlapping a channel region of the active layer, a first connection electrode contacting the first lower metal layer and a first conductive region of the active layer and including a plurality of first connection patterns spaced apart from each other along the first direction, and a second connection electrode contacting the second lower metal layer and a second conductive region of the active layer and including a plurality of second connection patterns spaced apart from each other along the first direction. A power module includes a power supply module that is configured to supply an external power, and a power conversion module that is configured to convert the external power supplied by the power supply module to generate a power voltage provided to the pixels.

Each of the first connection patterns may contact the first lower metal layer through a separation space between two adjacent active patters among the active patterns, and each of the second connection patterns may contact the second lower metal layer through the separation space.

A plurality of first holes penetrating a portion of the first conductive region and spaced apart from each other and a plurality of second holes penetrating a portion of the second conductive region and spaced apart from each other may be defined in each of the active patterns. In one active pattern, among the active patterns, the first holes and the second holes may be alternatively arranged along a second direction intersecting the first direction. Each of the first holes may be located between the first connection patterns and each of the second holes may be located between the second connection patterns.

The display device may further include a gate insulating layer disposed between the active layer and the gate electrode, and in which a first opening area exposing the first holes and the first conductive region, and a second opening area exposing the second holes and the second conductive region are defined. Opposite ends, in the first direction, of the first opening area may overlap the first connection patterns and opposite ends, in the first direction, of the second opening area may overlap the second connection patterns.

The opposite ends, in the first direction, of the first opening area may coincide with opposite ends, in the first direction, of each of the first holes. The opposite ends, in the first direction, of the second opening area may coincide with opposite ends, in the first direction, of each of the second holes.

A display device may include a gate driver disposed in a peripheral area and including at least one buffer transistor including a metal oxide semiconductor. A first connection electrode, which serves as a drain electrode of the buffer transistor, may contact a first bottom metal layer and a first conductive region of an active layer, and may include a plurality of first connection patterns spaced apart from each other along a first direction. A second connection electrode, which serves as a source electrode, may contact a second bottom metal layer and a second conductive region of the active layer, and may include a plurality of second connection patterns spaced apart from each other along the first direction.

In addition, the first connection patterns may contact the first conductive region through a first opening area of a gate insulating layer, and the second connection patterns may contact the second conductive region through a second opening area of the gate insulating layer. In this case, opposite ends of the first opening area, in the first direction, may overlap the first connection patterns, and opposite ends of the second opening area, in the first direction, may overlap the second connection patterns.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a plan view illustrating a display device according to embodiments of the present disclosure.

FIG. 2 is a cross-sectional view illustrating a display panel included in the display device of FIG. 1.

FIG. 3 is an equivalent circuit diagram illustrating one pixel of FIG. 1.

FIG. 4 is a plan view illustrating a transistor included in one pixel of FIG. 1.

FIG. 5 is a cross-sectional view taken along line I-I’ of FIG. 4.

FIG. 6 is a schematic drawing illustrating one stage included in a gate driver of FIG. 1.

FIG. 7 is a plan view illustrating an example of a buffer transistor of a buffer circuit part included in one stage of FIG. 6.

FIG. 8 is a cross-sectional view taken along line II-II’ of FIG. 7.

FIGS. 9, 10, 11, 12, 13, 14, 15, 16, and 17, are cross-sectional views for explaining a method for manufacturing the display device of FIG. 8.

FIG. 18 is a plan view illustrating an example of a buffer transistor of a buffer circuit part included in one stage of FIG. 6.

FIG. 19 is a cross-sectional view taken along line III-III’ of FIG. 18.

FIG. 20 is a block diagram illustrating an electronic device according to embodiments of the present disclosure.

FIG. 21 is a schematic diagram illustrating an electronic device according to various embodiments.

### DETAILED DESCRIPTION OF THE EMBODIMENTS

Hereinafter, embodiments of the present disclosure will be explained in detail with reference to the accompanying drawings. The same reference numerals may be used for the same components in the drawings, and to the extent that an element is not described in detail with respect to this figure, it may be understood that the element is at lea.

In the present specification, a plane may be defined by a first direction DR1 and a second direction DR2 intersecting the first direction DR1. For example, the second direction DR2 may be perpendicular to the first direction DR1. In addition, a third direction DR3 may be a normal direction to the plane. For example, the third direction DR3 may be perpendicular to the plane.

Embodiments of the present disclosure relate to an advanced display device architecture designed to increase space efficiency and performance by optimizing the layout and structure of buffer transistors in the peripheral area of a display panel. The device includes a substrate having a display area, where pixels are arranged, and a surrounding peripheral area that houses driving circuits. Within this peripheral area, a gate driver includes at least one buffer transistor. The buffer transistor employs multiple lower metal layers, an active semiconductor layer patterned into multiple segments, and a gate electrode arranged over a channel region. This arrangement allows the buffer transistor to generate and transmit gate signals while occupying less space, thereby reducing the non-active “dead space” around the display area.

An aspect of the present disclosure is the introduction of first and second connection electrodes, each subdivided into multiple connection patterns aligned along a defined direction. These electrodes connect the metal layers to conductive regions of the active semiconductor through openings in a gate insulating layer. The inclusion of holes defined within the conductive regions further facilitates current flow and reliable electrical contact. The design ensures that the ends of the openings overlap with the connection patterns, which allows the transistor dimensions to be reduced without compromising electrical integrity. Such structural improvements make the transistor more compact while ensuring stable operation.

The device also supports integration into electronic devices by coupling the display panel with a power module that converts external power for the pixels. Manufacturing methods are provided, demonstrating the sequential formation of metal layers, buffer layers, active semiconductor patterns, insulating layers, electrodes, and passivation layers. The refined structural features of the buffer transistor allow for simplified routing, minimized parasitic effects, and enhanced durability. Altogether, embodiments of the present disclosure provide a display device that increases active display area, improves image quality, and facilitates more compact and efficient electronic devices.

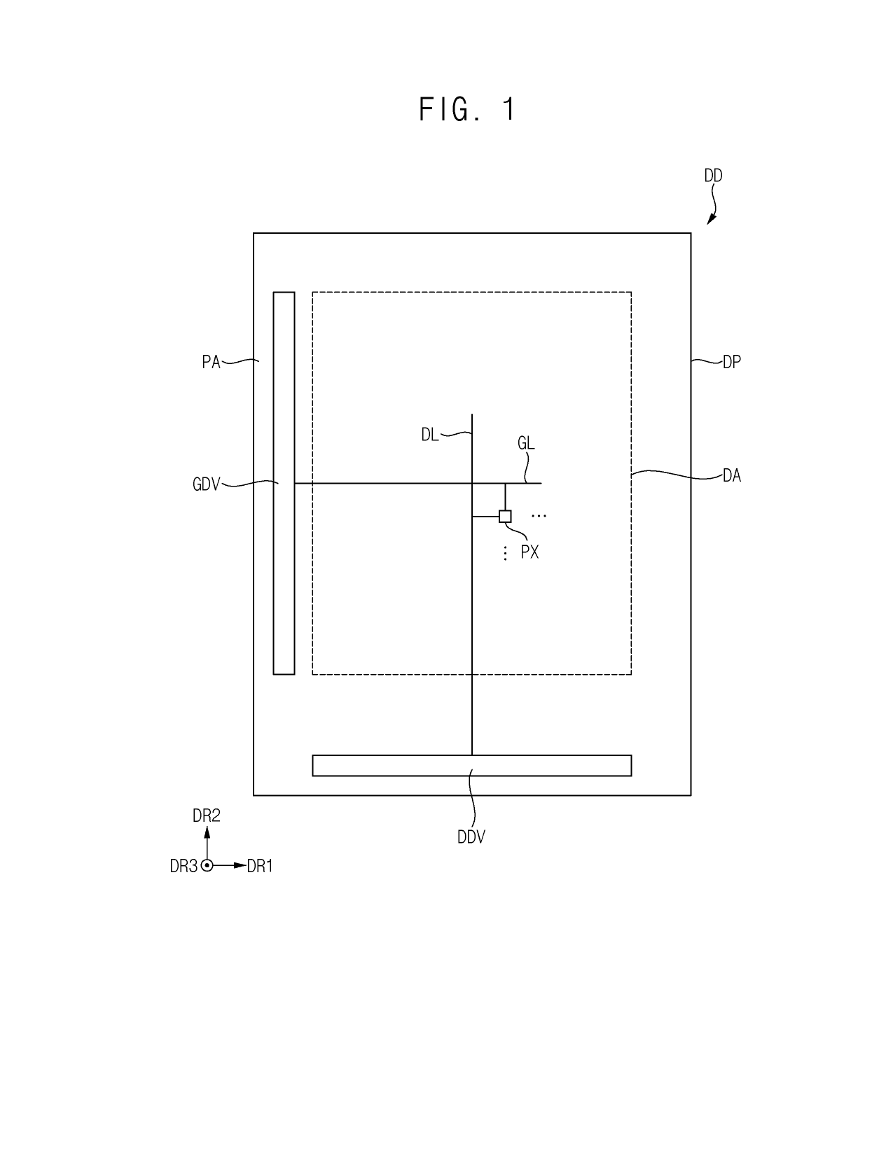

FIG. 1 is a plan view illustrating a display device according to embodiments of the present disclosure.

Referring to FIG. 1, a display device DD, according to the embodiments of the present disclosure, may include a display panel DP, a gate driver GDV, and a data driver DDV.

The display device DD may have a rectangular planar shape (e.g., a rectangular planar shape with rounded corners). However, the embodiments of the present disclosure are not necessarily limited thereto, and the display device DD may have various planar shapes.

The display panel DP may include a display area DA and a peripheral area PA. The display area DA may be an area for displaying an image by generating light or by adjusting the transmittance of light provided from an external light source. The peripheral area PA may be an area which does not display an image. The peripheral area PA may be located around the display area DA. For example, the peripheral area PA may entirely surround the display area DA or may surround the display area DA on at least two opposite sides thereof.

The display panel DP may include a plurality of pixels PX, gate lines GL, and data lines DL. The pixels PX may be arranged in the display area DA. For example, the pixels PX may be arranged in a matrix along the first direction DR1 and the second direction DR2 intersecting the first direction DR1. Each pixel PX may include a driving transistor which generates a driving current, and a light-emitting element (e.g., an organic light-emitting diode) that is electrically connected to the driving transistor and generates light based on the driving current. Accordingly, the display area DA may display an image by the pixels PX which emits light.

In the peripheral area PA, drivers for driving the pixels PX may be disposed. For example, the drivers may include the gate driver GDV and the data driver DDV.

For example, the gate driver GDV may be integrated or formed in the peripheral area PA. Alternatively, the gate driver GDV may be implemented with one or more integrated circuits (ICs).

For example, the data driver DDV may be implemented as a single integrated circuit, which may be referred to as a timing controller embedded data driver (TED). Alternatively, the data driver DDV may be implemented with separate integrated circuits.

The gate line GL may be electrically connected to the gate driver GDV and may extend along the first direction DR1. The gate line GL may receive a gate signal from the gate driver GDV and transmit the gate signal to the pixels PX.

The data line DL may be electrically connected to the data driver DDV and may extend along the second direction DR2. The data line DL may receive a data voltage from the data driver DDV and transmit the data voltage to the pixels PX.

For example, as illustrated in FIG. 1, the data driver DDV may be directly disposed on the display panel DP. Alternatively, the data driver DDV may be disposed on a circuit board (e.g., a printed circuit board (PCB) or a flexible printed circuit board (FPCB)) electrically connected to a pad electrode disposed at one side of the peripheral area PA.

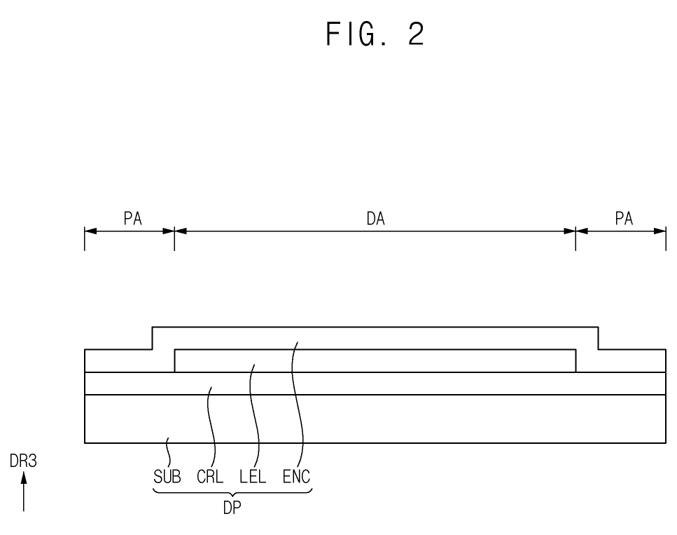

FIG. 2 is a cross-sectional view illustrating a display panel included in the display device of FIG. 1.

Referring to FIG. 2, the display panel DP may include a substrate SUB, a circuit layer CRL, a light-emitting element layer LEL, and an encapsulation layer ENC.

The substrate SUB may be a glass substrate, a metal substrate, or a polymer substrate. For example, the substrate SUB may be a glass substrate. However, the embodiments of the present disclosure are not necessarily limited thereto, and the substrate SUB may be an inorganic layer, an organic layer, or a composite material layer.

The circuit layer CRL may be disposed on the substrate SUB. The circuit layer CRL may be disposed in the display area DA and the peripheral area PA. For example, the circuit layer CRL may include at least one insulating layer, a semiconductor element (e.g., a thin-film transistor), a conductive pattern, a signal line, and the like.

The light-emitting element layer LEL may be disposed on the circuit layer CRL. The light-emitting element layer LEL may be disposed in the display area DA. The light-emitting element layer LEL may include light-emitting elements which generate light. For example, the light-emitting elements may include organic light-emitting materials, inorganic light-emitting materials, organic-inorganic hybrid light-emitting materials, quantum dots, micro LEDs, or nano LEDs.

The encapsulation layer ENC may be disposed on the circuit layer CRL and the light-emitting element layer LEL. The encapsulation layer ENC may be disposed in the display area DA and at least a portion of the peripheral area PA. The encapsulation layer ENC may protect the light-emitting element layer LEL from foreign substances such as moisture, oxygen, and the like. For example, the encapsulation layer ENC may include at least one inorganic layer and at least one organic layer. In an embodiment, the encapsulation layer ENC may have a stacked structure of a first inorganic layer, an organic layer, and a second inorganic layer.

Thus, the display device DD may include a display panel DP with a central display area DA made up of pixels PX arranged in a matrix, each pixel PX having a driving transistor and a light-emitting element, while the surrounding peripheral area PA houses the gate driver GDV and data driver DDV that supply signals and voltages through gate GL and data lines DL. The panel is constructed on a substrate SUB with a circuit layer CRL, a light-emitting element layer LEL, and a protective encapsulation layer ENC, enabling reliable image display while protecting the elements from moisture and oxygen.

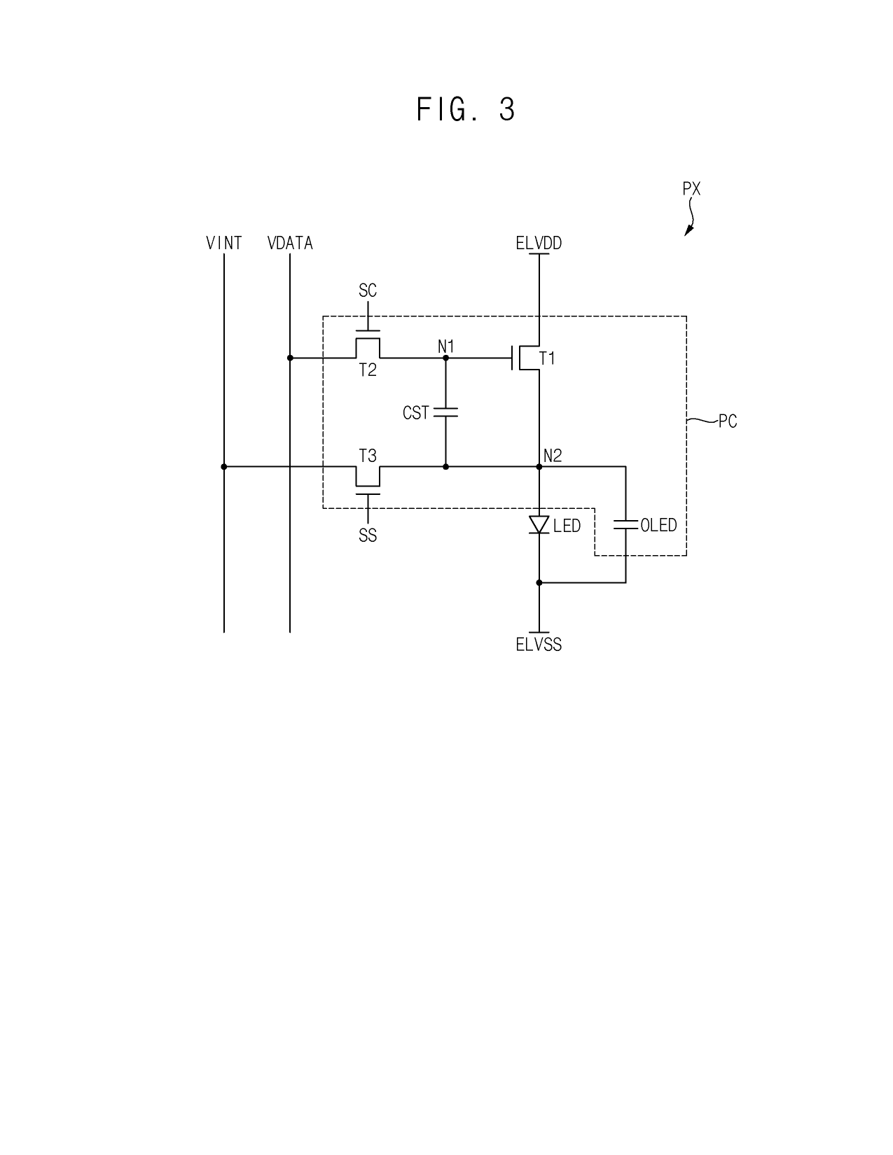

FIG. 3 is an equivalent circuit diagram illustrating one pixel of FIG. 1.

Referring to FIG. 3, a pixel PX may include a pixel driving circuit part PC and a light-emitting element LED electrically connected to the pixel driving circuit part PC. The pixel driving circuit part PC may generate a driving current, and the light-emitting element LED may generate light based on the driving current.

For example, the pixel driving circuit part PC may include a first transistor T1, a second transistor T2, a third transistor T3, a storage capacitor CST, and a light-emitting part capacitor CLED.

In an embodiment, the first transistor T1, the second transistor T2, and the third transistor T3 may all be P-channel metal-oxide-semiconductor (PMOS) transistors. However, the embodiments of the present disclosure are not necessarily limited thereto, and at least some of the first transistor T1, the second transistor T2, and the third transistor T3 may be N-channel metal-oxide-semiconductor (NMOS) transistors, and the remaining may be PMOS transistors.

In case that the pixel driving circuit part PC includes both NMOS transistor PMOS transistor and, an active pattern of the NMOS transistor may include a metal oxide semiconductor, and an active pattern of the PMOS transistor may include a silicon semiconductor. However, the embodiments of the present disclosure are not necessarily limited thereto, and the active pattern of the NMOS transistor may include a silicon semiconductor, and the active pattern of the PMOS transistor may include a metal oxide semiconductor.

The first transistor T1 may include a gate electrode, a first electrode, and a second electrode. The gate electrode of the first transistor T1 may be connected to a first node N1. The first electrode of the first transistor T1 may receive a first power supply voltage ELVDD. The second electrode of the first transistor T1 may be connected to a second node N2. The first transistor T1 may receive the first power supply voltage ELVDD in response to a voltage of the first node N1 and provide the driving current to the light-emitting element LED. The first transistor T1 may be referred to as a driving transistor for operating the light-emitting element LED.

The second transistor T2 may include a gate electrode, a first electrode, and a second electrode. The gate electrode of the second transistor T2 may receive a first gate signal SC. The first electrode of the second transistor T2 may receive a data voltage VDATA. The second electrode of the second transistor T2 may be connected to the first node N1.

The second transistor T2 may be turned on or off in response to the first gate signal SC. For example, in case that the first gate signal SC has an active level, the second transistor T2 may be turned on. In this case, the second transistor T2 may provide the data voltage VDATA to the first node N1. Conversely, in case that the first gate signal SC has an inactive level, the second transistor T2 may be turned off. In this case, the second transistor T2 may block the supply of the data voltage VDATA.

The third transistor T3 may include a gate electrode, a first electrode, and a second electrode. The gate electrode of the third transistor T3 may receive a second gate signal SS. The first electrode of the third transistor T3 may receive an initialization voltage VINT. The second electrode of the third transistor T3 may be connected to one end of the storage capacitor CST connected to the second node N2.

The third transistor T3 may be turned on or off in response to the second gate signal SS. For example, in case that the second gate signal SS has an active level, the third transistor T3 may be turned on. In this case, the third transistor T3 may provide the initialization voltage VINT to the second node N2. Conversely, in case that the second gate signal SS has an inactive level, the third transistor T3 may be turned off. In this case, the third transistor T3 may block the supply of the initialization voltage VINT.

For example, the second transistor T2 and the third transistor T3 may be switching transistors.

In an embodiment, the first electrode of each of the first, second, and third transistors T1, T2, and T3 may be a drain electrode, and the second electrode of each of the first, second, and third transistors T1, T2, and T3 may be a source electrode. However, the embodiments of the present disclosure are not necessarily limited thereto, and the first electrode of at least one of the first, second, and third transistors T1, T2, and T3 may be a source electrode, and the second electrode of the remaining ones may be a drain electrode.

The storage capacitor CST may include a first electrode and a second electrode. The first electrode of the storage capacitor CST may be connected to the first node N1. The second electrode of the storage capacitor CST may be connected between the third transistor T3 and the second node N2. The storage capacitor CST may store a differential voltage between a gate voltage and a source voltage of the first transistor T1.

The light-emitting part capacitor CLED may include a first electrode and a second electrode. The first electrode of the light-emitting part capacitor CLED may be connected to the second node N2. The second electrode of the light-emitting part capacitor CLED may be connected to a cathode electrode of the light-emitting element LED. The light-emitting part capacitor CLED may allow a voltage across the light-emitting element LED to remain constant, such that the light-emitting element LED may emit light with a uniform luminance. Alternatively, the light-emitting part capacitor CLED may be omitted.

The light-emitting element LED may include an anode electrode and a cathode electrode. The anode electrode of the light-emitting element LED may be connected to the second node N2. The cathode electrode of the light-emitting element LED may receive a second power supply voltage ELVSS. The second power supply voltage ELVSS may have a voltage level lower than the first power supply voltage ELVDD. The light-emitting element LED may emit light with a luminance corresponding to the driving current provided from the pixel driving circuit part PC.

Although FIG. 2 illustrates that the pixel driving circuit part PC includes three transistors and two capacitors, the embodiments of the present disclosure are not necessarily limited thereto.

Thus, each pixel PX includes a pixel driving circuit part PC and a light-emitting element LED, where the driving circuit generates current and the LED emits light accordingly. The pixel driving circuit part PC is formed of a first transistor T1, second transistor T2, third transistor T3, a storage capacitor CST, and a light-emitting part capacitor CLED, with T1 serving as the driving transistor, T2 and T3 acting as switching transistors, CST storing the voltage differential for T1, and CLED stabilizing the voltage across the LED to ensure uniform luminance.

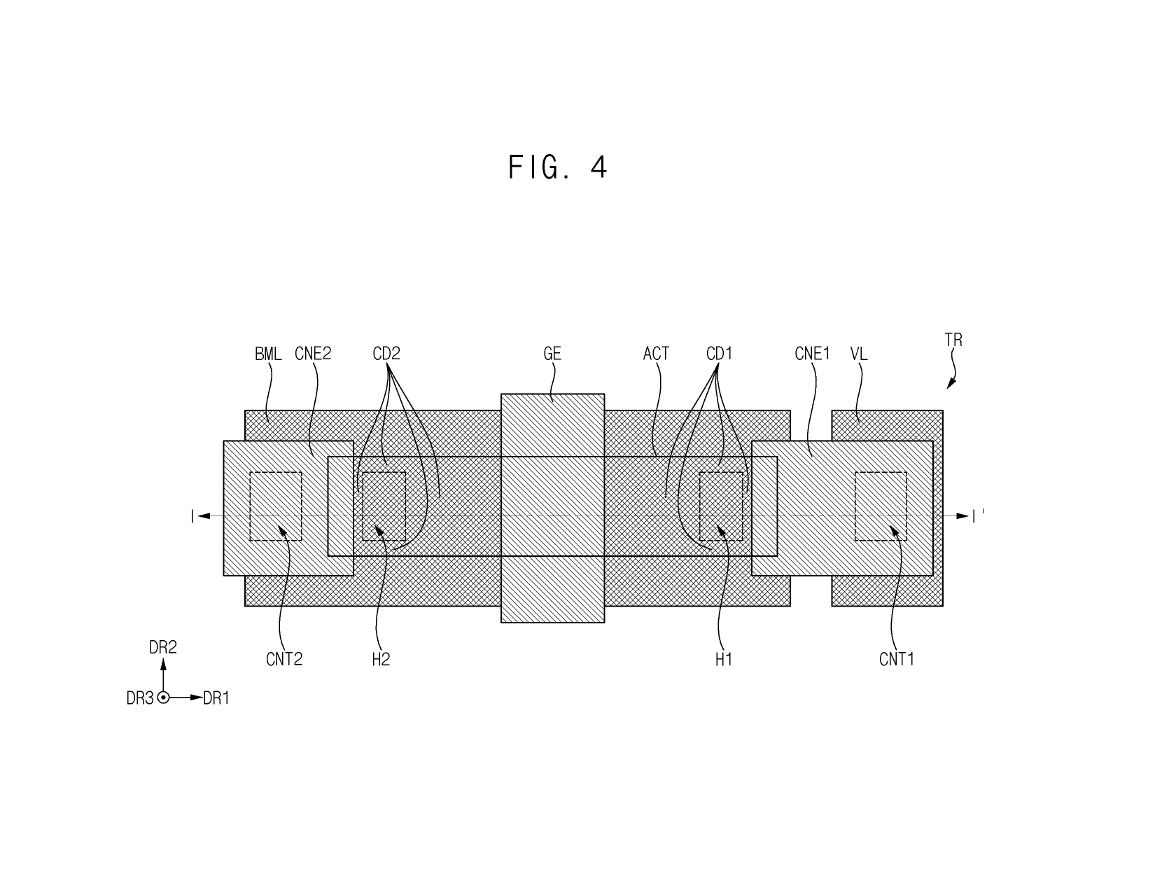

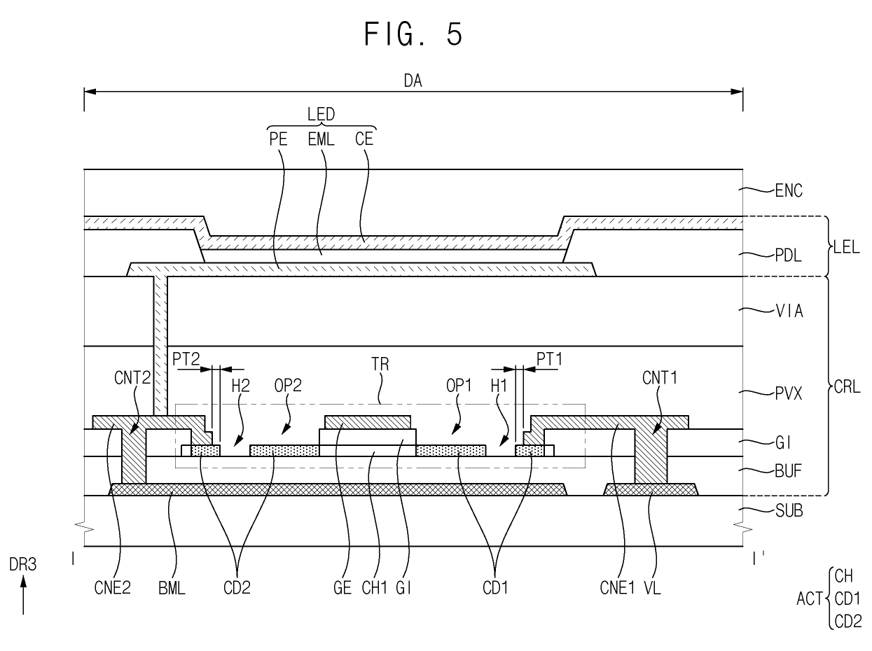

FIG. 4 is a plan view illustrating a transistor included in one pixel of FIG. 1. FIG. 5 is a cross-sectional view taken along line I-I’ of FIG. 4. For example, FIG. 5 is a cross-sectional view illustrating a portion of the display area DA of FIG. 1.

Referring to FIGS. 4 and 5, the display device DD, according to embodiments of the present disclosure, may include the substrate SUB, a buffer layer BUF, a bottom metal layer BML, a power supply line VL, a transistor TR, a gate insulating layer GI, a passivation layer PVX, a via insulating layer VIA, a pixel defining layer PDL, the light-emitting element LED, and the encapsulation layer ENC. The transistor TR may include an active pattern ACT, a gate electrode GE, a first connection electrode CNE1, and a second connection electrode CNE2. In addition, the light-emitting element LED may include a pixel electrode PE, a light-emitting layer EML, and a common electrode CE.

Here, the buffer layer BUF, the bottom metal layer BML, the power supply line VL, the transistor TR, the gate insulating layer GI, the passivation layer PVX, and the via insulating layer VIA may be components of the circuit layer CRL, and the pixel defining layer PDL and the light-emitting element LED may be components of the light-emitting element layer LEL.

The bottom metal layer BML may be disposed on the substrate SUB. The bottom metal layer BML may block external light incident on the transistor TR. In addition, the bottom metal layer BML may transmit signals and/or voltages to the transistor TR. The bottom metal layer BML may include a metal, an alloy, a metal nitride, a conductive metal oxide, a transparent conductive material, and the like. For example, the bottom metal layer BML may include molybdenum (Mo), an alloy containing molybdenum (Mo), titanium (Ti), an alloy containing titanium (Ti), and the like. These can be used alone or in combination with each other. However, the embodiments of the present disclosure are not necessarily limited thereto. The bottom metal layer BML may have a single-layer structure or a multi-layer structure in which a plurality of layers are stacked.

The power supply line VL may be disposed on the substrate SUB. The power supply line VL may be disposed in the same layer as the bottom metal layer BML. For example, the power supply line VL may include the same material as the bottom metal layer BML and may be formed through the same process as the bottom metal layer BML. For example, various voltages (e.g., the first power supply voltage ELVDD shown in FIG. 3) may be applied to the power supply line VL.

The buffer layer BUF may be disposed on the substrate SUB. The buffer layer BUF may cover the bottom metal layer BML and the power supply line VL. The buffer layer BUF may prevent diffusion of metal atoms or impurities from the substrate SUB to the transistor TR. In addition, in case that the surface of the substrate SUB is not uniform, the buffer layer BUF may improve the flatness of the surface of the substrate SUB. For example, the buffer layer BUF may include an inorganic insulating material such as silicon oxide (SiOₓ), silicon nitride (SiNₓ), silicon oxynitride (SiOₓN_{y}), and the like. These can be used alone or in combination with each other. The buffer layer BUF may have a single-layer structure or a multi-layer structure in which a plurality of layers are stacked.

The active pattern ACT may be disposed on the buffer layer BUF. In an embodiment, the active pattern ACT may include a metal oxide semiconductor. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO) and the like containing indium (In), zinc (Zn), gallium (Ga), tin (Sn), titanium (Ti), aluminum (Al), hafnium (Hf), zirconium (Zr), magnesium (Mg), and the like. These can be used alone or in combination with each other. In an embodiment, the active pattern ACT may include indium gallium zinc oxide (IGZO). However, the embodiments of the present disclosure are not necessarily limited thereto.

The active pattern ACT may include a first conductive region CD1, a second conductive region CD2, and a channel region CH. The channel region CH may be located between the first conductive region CD1 and the second conductive region CD2. The first conductive region CD1 and the second conductive region CD2 may have higher conductivity than the channel region CH. For example, the first conductive region CD1 and the second conductive region CD2 may be n+-type doped regions. However, the embodiments of the present disclosure are not necessarily limited thereto.

Both ends of the active pattern ACT may be non-conductive, inactive regions. The inactive regions of the active pattern ACT may be covered by the gate insulating layer GI and may overlap the first connection electrode CNE1 and the second connection electrode CNE2 in the plan view.

A first hole H1 and a second hole H2 exposing at least a portion of an upper surface of the buffer layer BUF may be defined in the active pattern ACT. For example, the first hole H1 may penetrate a portion of the first conductive region CD1, and the second hole H2 may penetrate a portion of the second conductive region CD2. In an embodiment, the first hole H1 may be located between the gate electrode GE and the first connection electrode CNE1 in the plan view, and the second hole H2 may be located between the gate electrode GE and the second connection electrode CNE2 in the plan view.

In an embodiment, the first hole H1 may be surrounded by the first conductive region CD1, and the second hole H2 may be surrounded by the second conductive region CD2. Accordingly, current may flow to both ends facing each other in the second direction DR2 of the first conductive region CD1, and current may flow to both ends facing each other in the second direction DR2 of the second conductive region CD2.

In an embodiment, the first conductive region CD1 may include a first protrusion PT1, and the second conductive region CD2 may include a second protrusion PT2. The first protrusion PT1 may denote a portion of the first conductive region CD1 exposed by the first connection electrode CNE1, and may be disposed between the first connection electrode CNE1 and the first hole H1 in the plan view. The second protrusion PT2 may denote a portion of the second conductive region CD2 exposed by the second connection electrode CNE2, and may be disposed between the second connection electrode CNE2 and the second hole H2 in the plan view.

The gate insulating layer GI may be disposed on the buffer layer BUF and the active pattern ACT. The gate insulating layer GI may cover at least a portion of the active pattern ACT. In an embodiment, a first opening area OP1 exposing the first conductive region CD1 and the first hole H1, and a second opening area OP2 exposing the second conductive region CD2 and the second hole H2 may be defined in the gate insulating layer GI. For example, the gate insulating layer GI may cover the remaining areas of the active pattern ACT except for the first conductive region CD1 and the second conductive region CD2.

For example, the gate insulating layer GI may include an inorganic insulating material such as silicon oxide (SiOₓ), silicon nitride (SiNₓ), silicon oxynitride (SiOxN_{y}), and the like. These can be used alone or in combination with each other. The gate insulating layer GI may have a single-layer structure or a multi-layer structure in which a plurality of layers are stacked.

The gate electrode GE may be disposed on the gate insulating layer GI. The gate electrode GE may overlap the channel region CH in the plan view. For example, the gate electrode GE may include a metal, an alloy, a metal nitride, a conductive metal oxide, a transparent conductive material, and the like. Examples of metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of conductive metal oxide may include indium tin oxide, indium zinc oxide, and the like. Examples of metal nitride may include aluminum nitride (AlNₓ), tungsten nitride (WNₓ), chromium nitride (CrNₓ), and the like. These can be used alone or in combination with each other.

The gate electrode GE may have a single-layer structure or a multi-layer structure in which a plurality of layers are stacked. In an embodiment, the gate electrode GE may have a stacked structure including a first layer including titanium (Ti) and a second layer including copper (Cu). However, the embodiments of the present disclosure are not necessarily limited thereto.

The first connection electrode CNE1 and the second connection electrode CNE2 may be disposed on the gate insulating layer GI. The first connection electrode CNE1 and the second connection electrode CNE2 may face each other in the first direction DR1.

The first connection electrode CNE1 may be connected to (or may contact) the power supply line VL through a first contact hole CNT1 penetrating the buffer layer BUF and the gate insulating layer GI. The second connection electrode CNE2 may be connected to (or may contact) the bottom metal layer BML through a second contact hole CNT2 penetrating the buffer layer BUF and the gate insulating layer GI.

In addition, the first connection electrode CNE1 may be connected to (or may contact) the first conductive region CD1 through the first opening area OP1, and the second connection electrode CNE2 may be connected to (or may contact) the second conductive region CD2 through the second opening area OP2. For example, the first connection electrode CNE1 may extend into the first opening area OP1, and the second connection electrode CNE2 may extend into the second opening area OP2. In this case, the first connection electrode CNE1 might not overlap the first hole H1 in the plan view, and the second connection electrode CNE2 might not overlap the second hole H2 in the plan view.

Accordingly, the first connection electrode CNE1 may electrically connect the power supply line VL and the active pattern ACT, and the second connection electrode CNE2 may electrically connect the bottom metal layer BML and the active pattern ACT.

In an embodiment, the first connection electrode CNE1 and the second connection electrode CNE2 may be disposed in the same layer as the gate electrode GE. For example, the first connection electrode CNE1 and the second connection electrode CNE2 may include the same material as the gate electrode GE and may be formed through the same process as the gate electrode GE.

The passivation layer PVX may be disposed on the gate insulating layer GI, the gate electrode GE, the first connection electrode CNE1, and the second connection electrode CNE2. The passivation layer PVX may cover the gate insulating layer GI, the gate electrode GE, the first connection electrode CNE1, and the second connection electrode CNE2, and may fill the first and second holes H1 and H2 and the first and second opening areas OP1 and OP2. For example, the passivation layer PVX may include an inorganic insulating material such as silicon oxide (SiOₓ), silicon nitride (SiNₓ), silicon oxynitride (SiOₓN_{y}), and the like. These can be used alone or in combination with each other.

The via insulating layer VIA may be disposed on the passivation layer PVX. The via insulating layer VIA may have a substantially flat upper surface. The via insulating layer VIA may include an organic insulating material. For example, the via insulating layer VIA may include an organic material such as phenolic resin, polyacrylates resin, polyimides resin, polyamides resin, siloxane resin, epoxy resin, and the like. These can be used alone or in combination with each other. The via insulating layer VIA may have a single-layer structure or a multi-layer structure in which a plurality of layers are stacked.

The pixel electrode PE may be disposed on the via insulating layer VIA. The pixel electrode PE may be connected to the second connection electrode CNE2 through a contact hole penetrating the passivation layer PVX and the via insulating layer VIA. For example, the pixel electrode PE may include a metal, an alloy, a metal nitride, a conductive metal oxide, a transparent conductive material, and the like. These can be used alone or in combination with each other. In an embodiment, the pixel electrode PE may have a multilayer structure including ITO/Ag/ITO. However, the embodiments of the present disclosure are not necessarily limited thereto. The pixel electrode PE may be an anode electrode.

The pixel defining layer PDL may be disposed on the via insulating layer VIA. The pixel defining layer PDL may cover an edge of the pixel electrode PE. In addition, a pixel opening exposing at least a portion of an upper surface of the pixel electrode PE may be defined in the pixel defining layer PDL. For example, the pixel defining layer PDL may include an inorganic insulating material or an organic insulating material. In an embodiment, the pixel defining layer PDL may include an organic insulating material such as epoxy resin, siloxane resin, and the like. These can be used alone or in combination with each other. In another embodiment, the pixel defining layer PDL may include an inorganic and/or organic insulating material containing a light-shielding material such as black pigment, black dye, and the like.

The light-emitting layer EML may be disposed on the pixel electrode PE. For example, the light-emitting layer EML may be disposed in the pixel opening of the pixel defining layer PDL. The light-emitting layer EML may include a light-emitting material (e.g., an organic inorganic light-emitting material or an inorganic light-emitting material) which generates light of a predetermined color. For example, the light-emitting layer EML may include a light-emitting material which generates red light, green light, or blue light.

The common electrode CE may be disposed on the pixel defining layer PDL and the light-emitting layer EML. For example, the common electrode CE may include a metal, an alloy, a metal nitride, a conductive metal oxide, a transparent conductive material, and the like. These materials may be used alone or in combination. The common electrode CE may be a cathode electrode.

Accordingly, the light-emitting element LED including the pixel electrode PE, the light-emitting layer EML, and the common electrode CE may be formed in the display area DA. The light-emitting element LED may be electrically connected to the transistor TR. Accordingly, the light-emitting element LED may receive a driving signal from the transistor TR and generate light based on the driving signal.

The encapsulation layer ENC may be disposed on the common electrode CE. For example, the encapsulation layer ENC may include at least one inorganic layer and at least one organic layer.

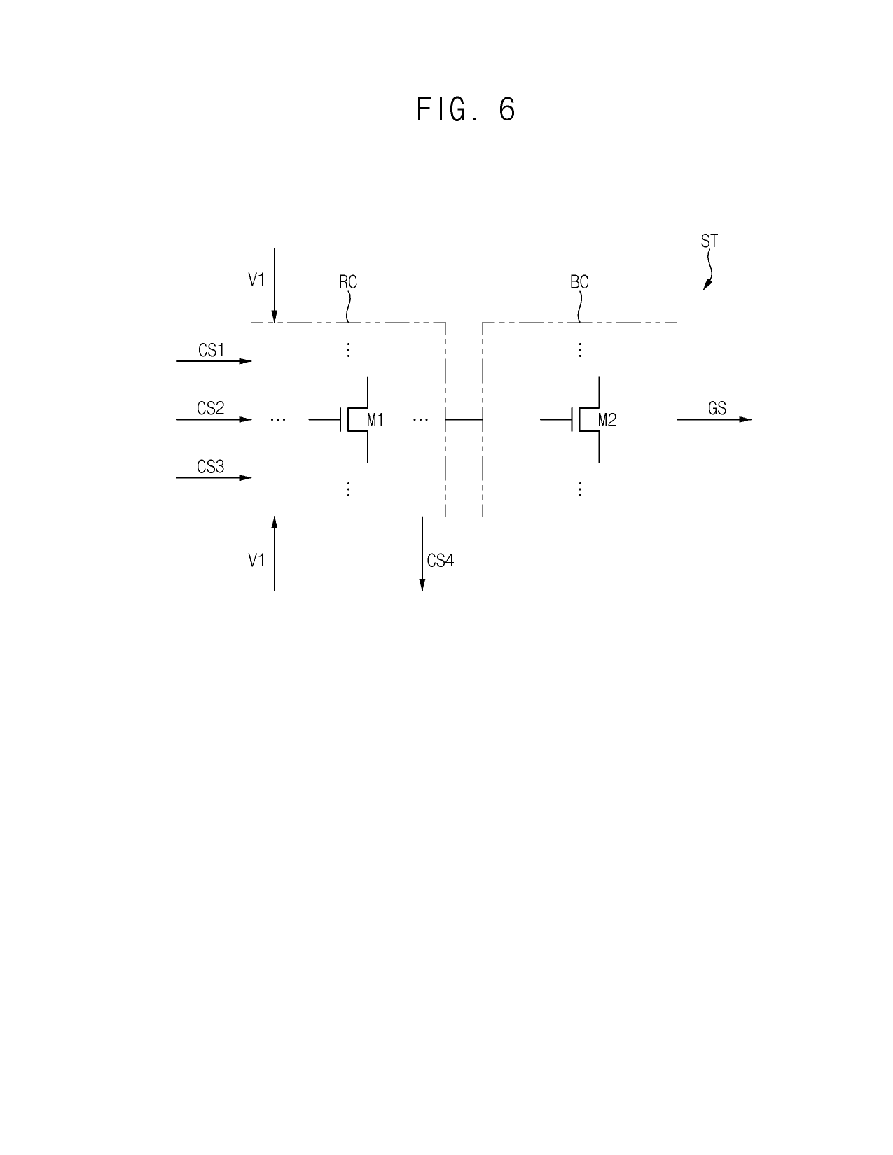

FIG. 6 is a schematic drawing illustrating one stage included in a gate driver of FIG. 1.

Referring to FIG. 6, the gate driver GDV may include a stage ST. For example, the stage ST included in the gate driver GDV may be provided in plural.

The stage ST may include a logic circuit part RC and a buffer circuit part BC electrically connected to the logic circuit part RC. The logic circuit part RC may control the buffer circuit part BC, and the buffer circuit part BC may output a gate signal GS to pixels (e.g., the pixels PX of FIG. 1). For example, the gate signal GS may include the first gate signal SC and the second gate signal SS of FIG. 3.

The logic circuit part RC may include a first transistor M1, and the buffer circuit part BC may include a second transistor M2. In an embodiment, the first transistor M1 and the second transistor M2 may include a metal oxide semiconductor. For convenience of explanation, FIG. 6 illustrates that each of the logic circuit part RC and the buffer circuit part BC includes a single transistor, but the logic circuit part RC may include a plurality of transistors, and the buffer circuit part BC may include at least one transistor. In the present specification, the second transistor M2 may be referred to as a buffer transistor. Hereinafter, the second transistor M2 will be referred to as the buffer transistor.

The logic circuit part RC may receive various control signals CS1, CS2, and CS3, and voltages V1 and V2, and may output a carry signal CS4. The carry signal CS4 may be provided to a subsequent stage. The buffer circuit part BC may output the gate signal GS.

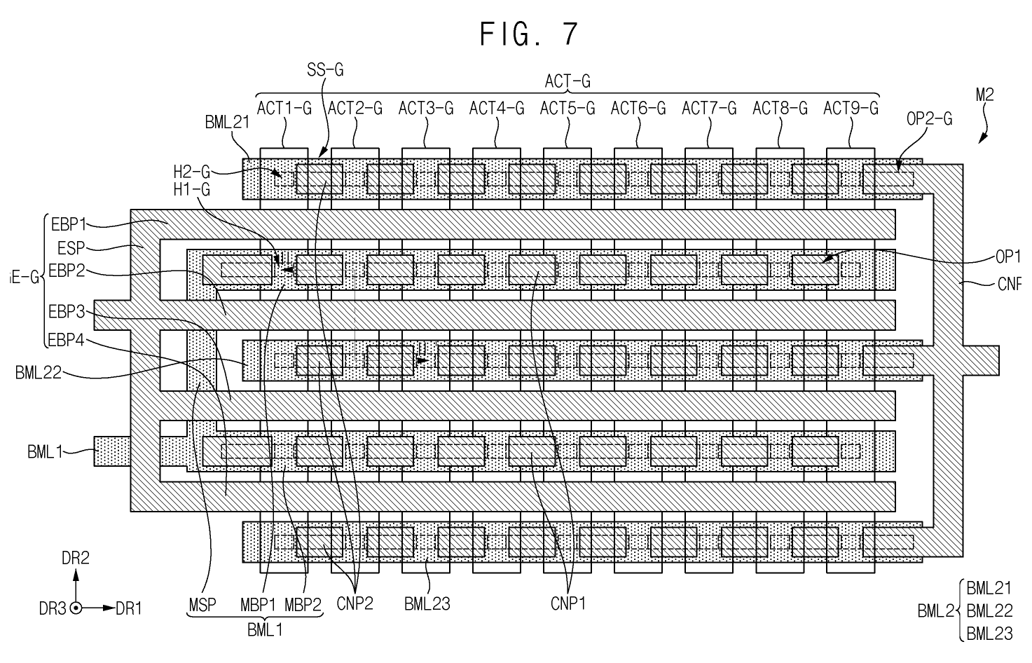

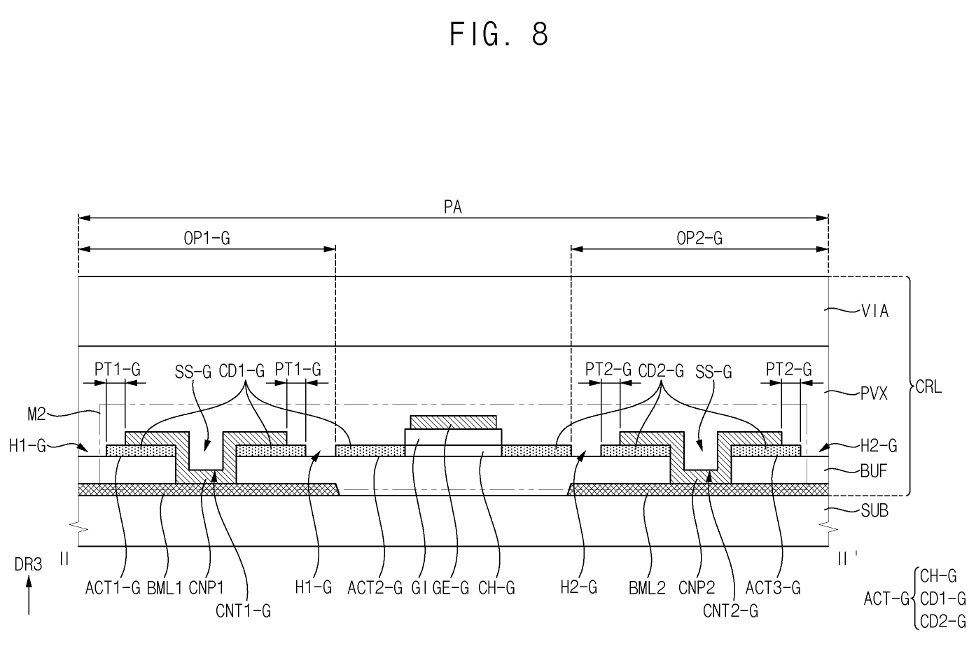

FIG. 7 is a plan view illustrating an example of a buffer transistor of a buffer circuit part included in one stage of FIG. 6. FIG. 8 is a cross-sectional view taken along line II-II’ of FIG. 7. For example, FIG. 8 is a cross-sectional view illustrating a portion of the peripheral area PA. Hereinafter, to the extent that an element is not described in detail with respect to this figure, it may be understood that the element is at least similar to a corresponding element that has been described elsewhere within the present disclosure, such as with respect to FIGS. 4 and 5.

Referring to FIGS. 7 and 8, the display device DD may further include a first bottom metal layer BML1, a second bottom metal layer BML2, and the buffer transistor M2 disposed in the peripheral area PA. The buffer transistor M2 may include an active layer ACT-G, a gate electrode GE-G, a first connection electrode, a second connection electrode, and a third connection pattern CNP3.

Here, the first bottom metal layer BML1, the second bottom metal layer BML2, and the buffer transistor M2 may be components of the circuit layer CRL.

The first bottom metal layer BML1 and the second bottom metal layer BML2 may be disposed on the substrate SUB. For example, the first bottom metal layer BML1 and the second bottom metal layer BML2 may include a metal, an alloy, a metal nitride, a conductive metal oxide, a transparent conductive material, and the like. These can be used alone or in combination with each other. Each of the first bottom metal layer BML1 and the second bottom metal layer BML2 may have a single-layer structure or a multi-layer structure in which a plurality of layers are stacked.

The first bottom metal layer BML1 and the second bottom metal layer BML2 may be disposed in the same layer as the bottom metal layer BML shown in FIGS. 4 and 5. For example, the first bottom metal layer BML1 and the second bottom metal layer BML2 may include the same material as the bottom metal layer BML of FIGS. 4 and 5 and may be formed through the same process the bottom metal layer BML of FIGS. 4 and 5.

In an embodiment, the first bottom metal layer BML1 may include a metal stem portion MSP extending in the second direction DR2 and a plurality of metal branch portions MBP1 and MBP2 extending from the metal stem portion MSP along the first direction DR1. The metal branch portions MBP1 and MBP2 may be spaced apart from each other along the second direction DR2. For example, the metal branch portions may include a first metal branch portion MBP1 and a second metal branch portion MBP2. The first bottom metal layer BML1 may receive a signal through the metal stem portion MSP.

In an embodiment, the second bottom metal layer BML2 may include a plurality of bottom metal patterns BML21, BML22, and BML23, each extending along the first direction DR1. The bottom metal patterns BML21, BML22, and BML23 may be spaced apart from one another along the second direction DR2. For example, the bottom metal patterns may include a first bottom metal pattern BML21, a second bottom metal pattern BML22, and a third bottom metal pattern BML23. The second bottom metal pattern BML22 may be disposed between the first metal branch portion MBP1 and the second metal branch portion MBP2 in the plan view.

The buffer layer BUF may extend from the display area DA of FIG. 5 to the peripheral area PA. The buffer layer BUF may cover the first bottom metal layer BML1 and the second bottom metal layer BML2.

The active layer ACT-G may be disposed on the buffer layer BUF. In an embodiment, the active layer ACT-G may include a metal oxide semiconductor. The active layer ACT-G may be disposed in the same layer as the active pattern ACT shown in FIGS. 4 and 5. For example, the active layer ACT-G may include the same material as the active pattern ACT and may be formed by the same process as the active pattern ACT.

In an embodiment, the active layer ACT-G may include a plurality of active patterns ACT1-G, ACT2-G, ACT3-G, ACT4-G, ACT5-G, ACT6-G, ACT7-G, ACT8-G, and ACT9-G, each extending in the second direction DR2. The active patterns ACT1-G, ACT2-G, ACT3-G, ACT4-G, ACT5-G, ACT6-G, ACT7-G, ACT8-G, and ACT9-G may be spaced apart from each other along the first direction DR1. Accordingly, a separation space SS-G may be formed between two adjacent active patterns among the active patterns ACT1-G, ACT2-G, ACT3-G, ACT4-G, ACT5-G, ACT6-G, ACT7-G, ACT8-G, and ACT9-G. For example, the active patterns may include a first active pattern ACT1-G, a second active pattern ACT2-G, a third active pattern ACT3-G, a fourth active pattern ACT4-G, a fifth active pattern ACT5-G, a sixth active pattern ACT6-G, a seventh active pattern ACT7-G, an eighth active pattern ACT8-G, and a ninth active pattern ACT9-G.

The active layer ACT-G may include a first conductive region CD1-G, a second conductive region CD2-G, and a channel region CH-G. For example, each of the active patterns ACT1-G, ACT2-G, ACT3-G, ACT4-G, ACT5-G, ACT6-G, ACT7-G, ACT8-G, and ACT9-G may include the first conductive region CD1-G, the second conductive region CD2-G, and the channel region CH-G. The channel region CH-G may be located between the first conductive region CD1-G and the second conductive region CD2-G. The first conductive region CD1-G and the second conductive region CD2-G may have higher conductivity than the channel region CH-G. For example, the first conductive region CD1-G and the second conductive region CD2-G may be n+-type doped regions. However, the embodiments of the present disclosure are not necessarily limited thereto.

A plurality of first holes H1-G and a plurality of second holes H2-G exposing at least a portion of the upper surface of the buffer layer BUF and are spaced apart from each other may be defined in the active layer ACT-G. The first holes H1-G may penetrate a portion of the first conductive region CD1-G, and the second holes H2-G may penetrate a portion of the second conductive region CD2-G. For example, the first holes H1-G and the second holes H2-G may be defined in each of the active patterns ACT1-G, ACT2-G, ACT3-G, ACT4-G, ACT5-G, ACT6-G, ACT7-G, ACT8-G, and ACT9-G.

In an embodiment, in one active pattern of the active patterns among ACT1-G, ACT2-G, ACT3-G, ACT4-G, ACT5-G, ACT6-G, ACT7-G, ACT8-G, and ACT9-G, the first holes H1-G and the second holes H2-G may be alternately arranged along the second direction DR2. In addition, the first holes H1-G may be repeatedly arranged along the first direction DR1, and the second holes H2-G may also be repeatedly arranged along the first direction DR1.

In an embodiment, the first holes H1-G may overlap the first bottom metal layer BML1 in the plan view, and the second holes H2-G may overlap the second bottom metal layer BML2 in the plan view.

In an embodiment, the first holes H1-G may be surrounded by the first conductive region CD1-G, and the second holes H2-G may be surrounded by the second conductive region CD2-G. Accordingly, current may flow into the first conductive region CD1-G surrounding the first holes H1-G, and current may flow into the second conductive region CD2-G surrounding the second holes H2-G.

In an embodiment, the first conductive region CD1-G may include a first protrusion PT1-G, and the second conductive region CD2-G may include a second protrusion PT2-G. The first protrusion PT1-G may denote a portion of the first conductive region CD1-G exposed by first connection patterns CNP1, which will be described later, and may be disposed between the first connection pattern CNP1 and the first hole H1-G in the plan view. The second protrusion PT2-G may denote a portion of the second conductive region CD2-G exposed by second connection patterns CNP2, which will be described later, and may be disposed between the second connection pattern CNP2 and the second hole H2-G in the plan view.

The gate insulating layer GI may extend from the display area DA of FIG. 5 to the peripheral area PA. The gate insulating layer GI may be disposed on the buffer layer BUF and the active layer ACT-G, and may cover at least a portion of the active layer ACT-G. For example, the gate insulating layer GI may cover the remaining region (i.e., the channel region CH-G) of the active layer ACT-G except for the first conductive region CD1-G and the second conductive region CD2-G.

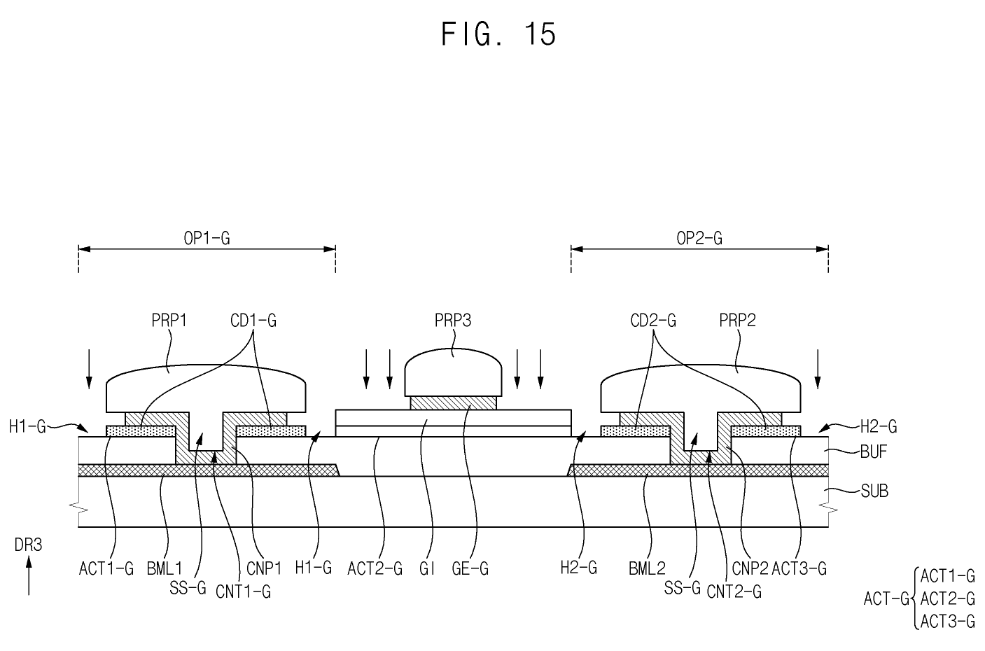

In an embodiment, a first opening area OP1-G exposing the first conductive region CD1-G and the first holes H1-G, and a second opening area OP2-G exposing the second conductive region CD2-G and the second holes H2-G may be defined in the gate insulating layer GI. At this time, both ends of the first opening area OP1-G parallel to the first direction DR1 may overlap the first connection patterns CNP1 in the plan view, and both ends of the second opening area OP2-G parallel to the first direction DR1 may overlap the second connection patterns CNP2 in the plan view. In this specification, the boundaries of the first opening area OP1-G and the second opening area OP2-G may be defined based on the gate insulating layer GI of FIG. 15.

In an embodiment, the first opening area OP1-G may overlap the first bottom metal layer BML1 in the plan view, and the second opening area OP2-G may overlap the second bottom metal layer BML2 in the plan view.

The first opening areas OP1-G may be plural and the second opening areas OP2-G may be plural. For example, the first opening areas OP1-G may be two correspond to the metal branch portions MBP1 and MBP2, and the second opening areas OP2-G may be three correspond to the bottom metal patterns BML21, BML22, and BML23.

In an embodiment, the first opening area OP1-G may continuously extend along the first direction DR1, and the second opening area OP2-G may also continuously extend along the first direction DR1.

In an embodiment, the both ends of the first opening area OP1-G parallel to the first direction DR1 may coincide with both ends of each of the first holes H1-G in the plan view, and the both ends of the second opening area OP2-G parallel to the first direction DR1 may coincide with both ends of each of the second holes H2-G.

The gate electrode GE-G may be disposed on the gate insulating layer GI. The gate electrode GE-G may overlap the channel region CH-G in the plan view.

In an embodiment, the gate electrode GE-G may include an electrode stem portion ESP extending along the second direction DR2, and a plurality of electrode branch portions EBP1, EBP2, EBP3, and EBP4 each extending from the electrode stem portion ESP along the first direction DR1. The electrode branch portions may be spaced apart from one another along the second direction DR2. For example, the electrode branch portions may include a first electrode branch portion EBP1, a second electrode branch portion EBP2, a third electrode branch portion EBP3, and a fourth electrode branch portion EBP4.

In an embodiment, each of the electrode branch portions EBP1, EBP2, EBP3, and EBP4 may be disposed between one metal branch portion among the metal branch portions MBP1 and MBP2 and one bottom metal pattern adjacent the one metal branch portion among bottom metal patterns BML21, BML22, and BML23 in the plan view. For example, the first electrode branch portion EBP1 may be disposed between the first bottom metal pattern BML21 and the first metal branch portion MBP1 in the plan view, the second electrode branch portion EBP2 may be disposed between the first metal branch portion MBP1 and the second bottom metal pattern BML22 in the plan view, the third electrode branch portion EBP3 may be disposed between the second bottom metal pattern BML22 and the second metal branch portion MBP2 in the plan view, and the fourth electrode branch portion EBP4 may be disposed between the second metal branch portion MBP2 and the third bottom metal pattern BML23 in the plan view.

The first connection electrode and the second connection electrode may be disposed on the gate insulating layer GI. In an embodiment, the first connection electrode may include a plurality of first connection patterns CNP1 spaced apart from each other along the first direction DR1, and the second connection electrode may include a plurality of second connection patterns CNP2 spaced apart from each other along the first direction DR1. Each of the first connection patterns CNP1 and the second connection patterns CNP2 may have an island shape. The first connection electrode may serve as a drain electrode, and the second connection electrode may serve as a source electrode.

Each of the first connection patterns CNP1 may be connected to (or may contact) the first bottom metal layer BML1 (for example, the metal branch portions MBP1 and MBP2) through a first contact hole CNT1-G penetrating the buffer layer BUF and a separation space SS-G spatially connected to the first contact hole CNT1-G. Each of the second connection patterns CNP2 may be connected to (or may contact) the second bottom metal layer BML2 (for example, the bottom metal patterns BML21, BML22, and BML23) through a second contact hole CNT2-G penetrating the buffer layer BUF and the separation space SS-G spatially connected to the second contact hole CNT2-G.

For example, each of the first connection patterns CNP1 may overlap the separation space SS-G in the plan view, and each of the second connection patterns CNP2 may overlap the separation space SS-G in the plan view.

In addition, each of the first connection patterns CNP1 may be connected to (or may contact) the first conductive region CD1-G through the first opening area OP1-G, and each of the second connection patterns CNP2 may be connected to (or may contact) the second conductive region CD2-G through the second opening area OP2-G. For example, the first connection patterns CNP1 may extend into the first opening area OP1-G, and the second connection patterns CNP2 may extend into the second opening area OP2-G.

The first connection patterns CNP1 might not overlap the first holes H1-G in the plan view, and the second connection patterns CNP2 might not overlap the second holes H2-G in the plan view. For example, in an embodiment, each of the first holes H1-G may be located between the first connection patterns CNP1 in the plan view, and each of the second holes H2-G may be located between the second connection patterns CNP2 in the plan view.

The third connection pattern CNP3 may be disposed on the gate insulating layer GI. The third connection pattern CNP3 may be connected to (or may contact) one end of the second bottom metal layer BML2, the first conductive region CD1-G, and the second conductive region CD2-G. The third connection pattern CNP3 may output a gate signal (e.g., the gate signal GS of FIG. 6).

Accordingly, the first connection patterns CNP1 may electrically connect the first bottom metal layer BML1 and the active layer ACT-G, and the second connection patterns CNP2 may electrically connect the second bottom metal layer BML2 and the active layer ACT-G. In this case, current may flow in the order of the first bottom metal layer BML1, the first connection patterns CNP1, the active layer ACT-G, the second connection patterns CNP2, and the second bottom metal layer BML2.

In an embodiment, the first connection patterns CNP1, the second connection patterns CNP2, the third connection pattern CNP3, and the gate electrode GE-G may be disposed in the same layer as the first connection electrode CNE1, the second connection electrode CNE2, and the gate electrode GE of FIGS. 4 and 5. For example, the first connection patterns CNP1, the second connection patterns CNP2, the third connection pattern CNP3, and the gate electrode GE-G may include the same material as the first and second connection electrodes CNE1 and CNE2 and the gate electrode GE, and may be formed through the same process as the first and second connection electrodes CNE1 and CNE2 and the gate electrode GE.

Accordingly, the buffer transistor M2 including the active layer ACT-G, the gate electrode GE-G, the first connection patterns CNP1, the second connection patterns CNP2, and the third connection pattern CNP3 may be formed in the peripheral area PA.

The passivation layer PVX may extend from the display area DA of FIG. 5 to the peripheral area PA. The passivation layer PVX may cover the gate insulating layer GI, the gate electrode GE-G, the first connection patterns CNP1, and the second connection patterns CNP2. In addition, the passivation layer PVX may fill the first and second holes H1-G and H2-G and the first and second opening areas OP1-G and OP2-G.

The via insulating layer VIA may extend from the display area DA of FIG. 5 to the peripheral area PA.

Referring again to FIGS. 1 to 8, the display device DD according to the embodiments of the present disclosure may include the gate driver GDV (for example, the buffer circuit part BC of the stage ST) disposed in the peripheral area PA and including at least one buffer transistor M2 including a metal oxide semiconductor. The first connection electrode, which serves as the drain electrode of the buffer transistor M2, may contact the first bottom metal layer BML1 and the first conductive region CD1-G of the active layer ACT-G, and may include the plurality of first connection patterns CNP1 spaced apart from each other along the first direction DR1. The second connection electrode, which serves as the source electrode, may contact the second bottom metal layer BML2 and the second conductive region CD2-G of the active layer ACT-G, and may include the plurality of second connection patterns CNP2 spaced apart from each other along the first direction DR1.

In addition, the first connection patterns CNP1 may contact the first conductive region CD1-G through the first opening area OP1-G of the gate insulating layer GI, and the second connection patterns CNP2 may contact the second conductive region CD2-G through the second opening area OP2-G of the gate insulating layer GI. In this case, the both ends of the first opening area OP1-G parallel to the first direction DR1 may overlap the first connection patterns CNP1 in the plan view, and the both ends of the second opening area OP2-G parallel to the first direction DR1 may overlap the second connection patterns CNP2 in the plan view. Accordingly, the size of the buffer transistor M2 may be relatively reduced. In this case, the dead space of the display device DD may be reduced.

Thus, the display device DD may include a detailed transistor TR structure formed on a substrate SUB with layers such as a buffer layer BUF bottom metal layer BML, gate insulating layer GI, passivation layer PVX, via insulating layer VIA, and encapsulation layer ENC, along with electrodes and connection patterns. The active pattern ACT within the transistor has conductive regions CD1, CD2, a channel region CH, holes H1, H2, and opening areas OP1, OP2 that enable electrical connection to first and second connection electrodes CNE1, CNE2, gate electrode GE, and bottom metal layers BML1, BML2, thereby supporting stable current flow. In the peripheral area PA, a buffer transistor M2 is constructed with an active layer ACT-G, connection patterns CNP1, CNP2, CNP3, and gate electrode GE-G, where the configuration of openings and overlaps allows for reduced transistor size and minimized dead space in the display panel.

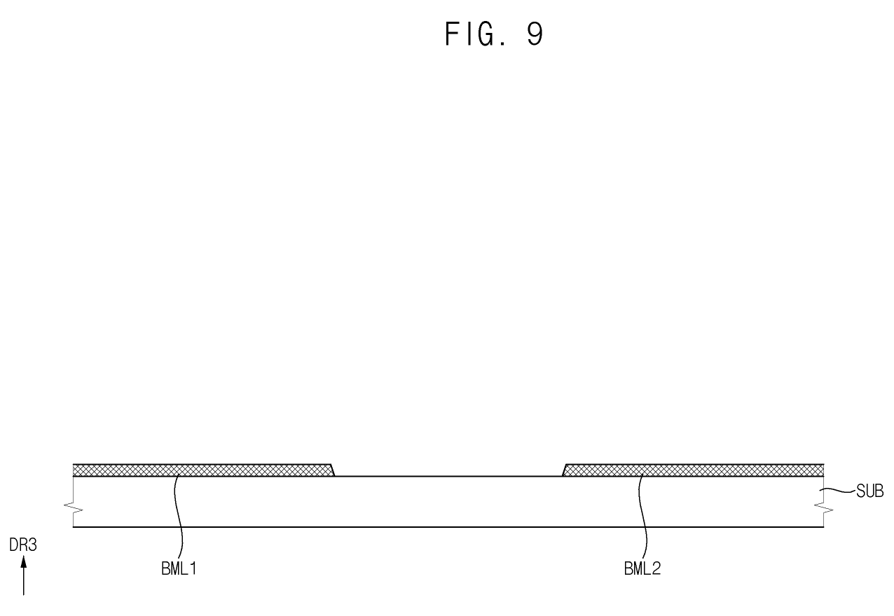

FIGS. 9 to 17 are cross-sectional views for explaining a method for manufacturing the display device of FIG. 8. Hereinafter, to the extent that an element is not described in detail with respect to this figure, it may be understood that the element is at least similar to a corresponding element that has been described elsewhere within the present disclosure, such as with respect to FIGS. 7 and 8.

Referring to FIG. 9, the first lower metal layer BML1 and the second lower metal layer BML2 may be formed in the peripheral area (e.g., the peripheral area PA in FIG. 8) on the substrate SUB. The first lower metal layer BML1 and the second lower metal layer BML2 may be simultaneously formed through the same process.

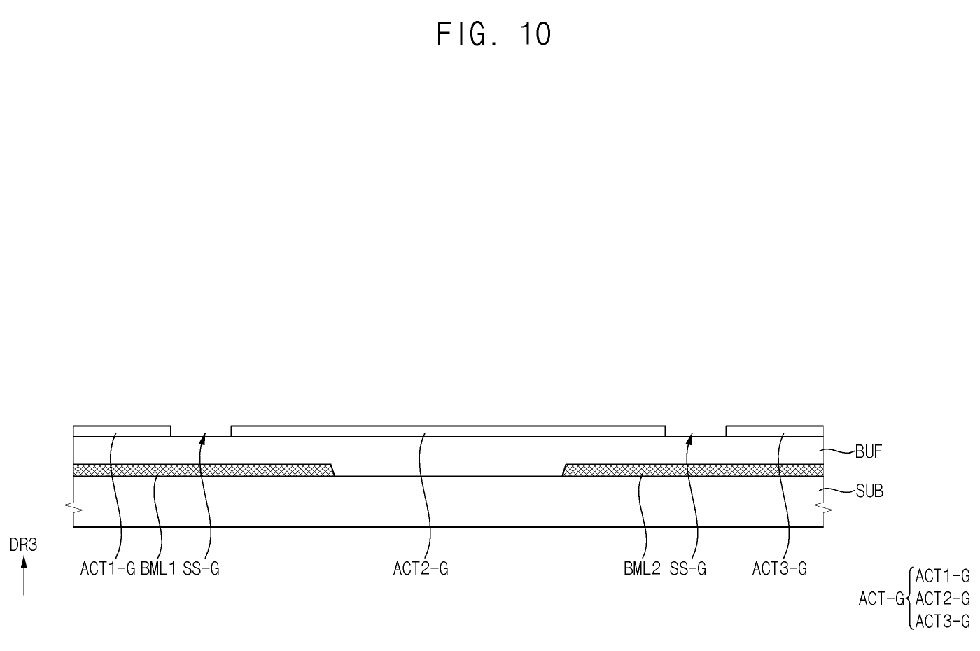

Referring to FIG. 10, the buffer layer BUF may be formed on the substrate SUB. The buffer layer BUF may cover the first lower metal layer BML1 and the second lower metal layer BML2. For example, the buffer layer BUF may be formed using an inorganic insulating material.

The active layer ACT-G including the first active pattern ACT1-G, the second active pattern ACT2-G, and the third active pattern ACT3-G spaced apart from each another may be formed in the peripheral area on the buffer layer BUF. For example, a semiconductor layer may be entirely formed on the buffer layer BUF and the semiconductor layer is patterned to form the first active pattern ACT1-G, the second active pattern ACT2-G, and the third active pattern ACT3-G.

In an embodiment, the active layer ACT-G may be formed using a metal oxide semiconductor.

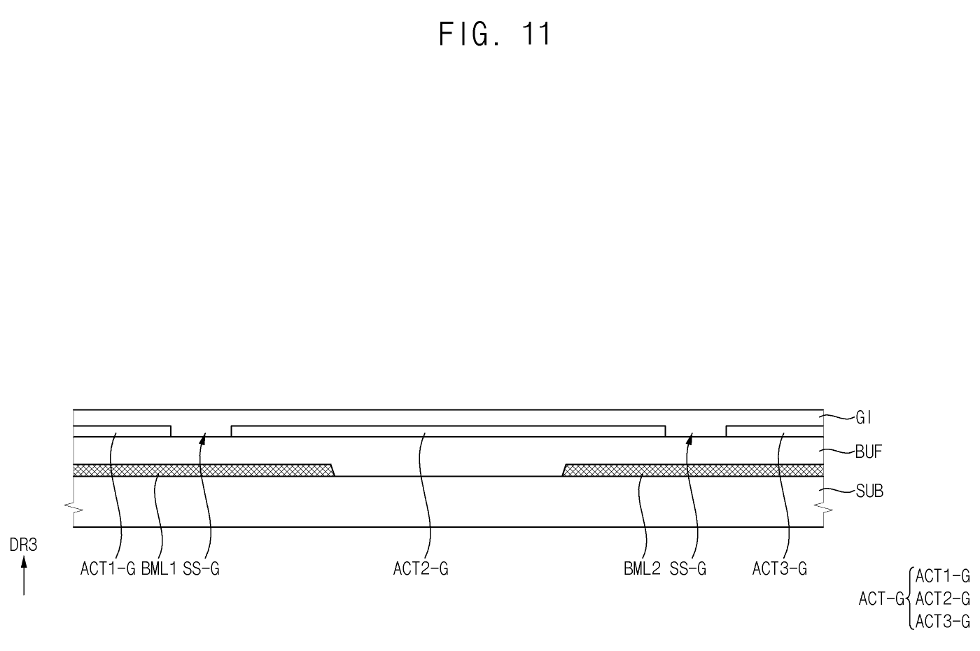

Referring to FIG. 11, a gate insulating layer GI may be entirely formed on the buffer layer BUF and the active layer ACT-G. The gate insulating layer GI may cover the active layer ACT-G. For example, the gate insulating layer GI may be formed using an inorganic insulating material.

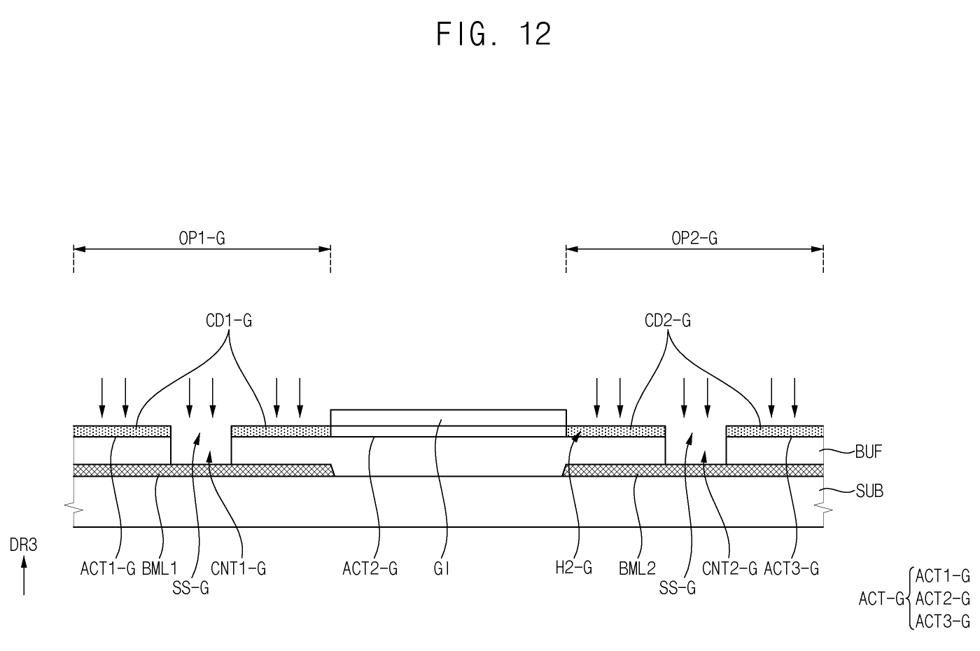

Referring to FIG. 12, through a first etching process, a portion of each of the gate insulating layer GI and the buffer layer BUF may be removed. Accordingly, the first opening area OP1-G overlapping the first lower metal layer BML1 in the plan view and the second opening area OP2-G overlapping the second lower metal layer BML2 in the plan view may be formed in the gate insulating layer GI. Simultaneously, a portion of the buffer layer BUF overlapping the separation space SS-G may be removed to form the first contact hole CNT1-G overlapping the opening region OP1-G and exposing at least portion of the first lower metal layer BML1, and the second contact hole CNT2-G overlapping the opening region OP2-G and exposing at least portion of the second lower metal layer BML2.

For example, the first etching process may be a dry etching process. However, the embodiments of the present disclosure are not necessarily limited thereto.

During the removal of the portion of the gate insulating layer GI by the first etching process, hydrogen included in the gate insulating layer GI may flow into the active layer ACT-G. The portion of the active layer ACT-G into which hydrogen is introduced from the gate insulating layer GI has a high carrier concentration due to the introduced hydrogen, thereby becoming conductive, and thus may become the first conducting region CD1-G and the second conducting region CD2-G. For example, the portion of each of the first active pattern ACT1-G and the second active pattern ACT2-G overlapping the first opening area OP1-G may become the first conductive region CD1-G, and the portion of each of the first active pattern ACT1-G and the third active pattern ACT3-G overlapping the second opening region OP2-G may become the second conductive region CD2-G.

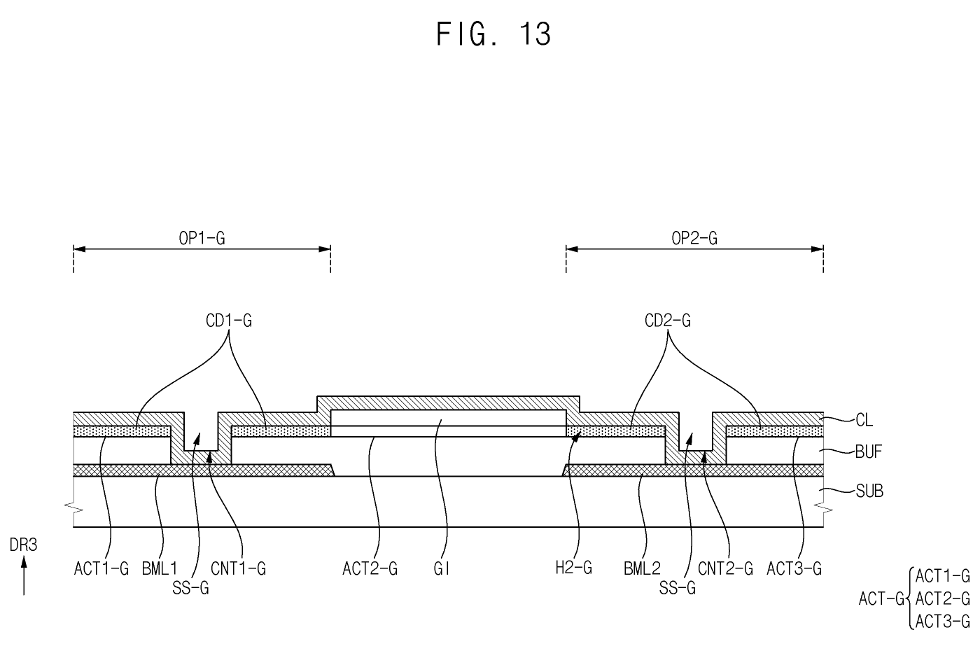

Referring to FIG. 13, a conductive layer CL may be entirely formed on the gate insulating layer GI and the active layer ACT-G. The conductive layer CL may fill the first and second opening areas OP1-G and OP2-G and the first and second contact holes CNT1-G and CNT2-G, and may contact the first lower metal layer BML1, the second lower metal layer BML2, the first conductive region CD1-G, and the second conductive region CD2-G.

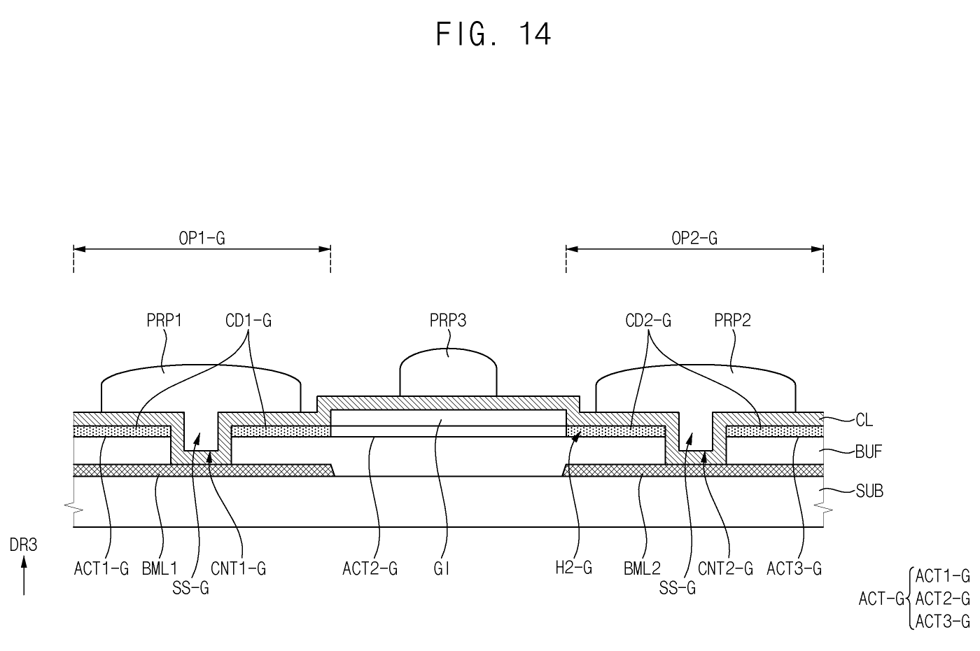

Referring to FIGS. 14 and 15, a photosensitive organic layer may be formed in the peripheral area on the conductive layer CL. By patterning the photosensitive organic layer, a first photoresist pattern PRP1, a second photoresist pattern PRP2, and a third photoresist pattern PRP3, which are spaced apart from each another, may be formed. The first photoresist pattern PRP1 may fill the first contact hole CNT1-G and correspond to an area where the first connection pattern CNP1 is to be formed, the second photoresist pattern PRP2 may fill the second contact hole CNT2-G and correspond to an area where the second connection pattern CNP2 is to be formed, and the third photoresist pattern PRP3 may correspond to an area where the gate electrode GE-G is to be formed.

For example, the first, second, and third photoresist patterns PRP1, PRP2, and PRP3 may include a positive photoresist. Alternatively, the first, second, and third photoresist patterns PRP1, PRP2, and PRP3 may include a negative photoresist.

Through a second etching process, a portion of the conductive layer CL may be removed using the first, second, and third photoresist patterns PRP1, PRP2, and PRP3 as masks. For example, portions of the conductive layer CL that do not overlap the first, second, and third photoresist patterns PRP1, PRP2, and PRP3 in the plan view may be removed. Accordingly, the first connection pattern CNP1 may be formed under the first photoresist pattern PRP1, the second connection pattern CNP2 under the second photoresist pattern PRP2, and the gate electrode GE-G under the third photoresist pattern PRP3. Simultaneously, the portion of the first conductive region CD1-G that do not overlap the gate insulating layer GI and the first, second, and third photoresist patterns PRP1, PRP2, and PRP3 in the plan view may be removed to form the first hole H1-G, and the portion of the second conductive region CD2-G that do not overlap the gate insulating layer GI and the first to third photoresist patterns PRP1, PRP2, and PRP3 in the plan view may be removed to form the second hole H2-G.

For example, the second etching process may be a wet etching process. However, the embodiments of the present disclosure are not necessarily limited thereto.

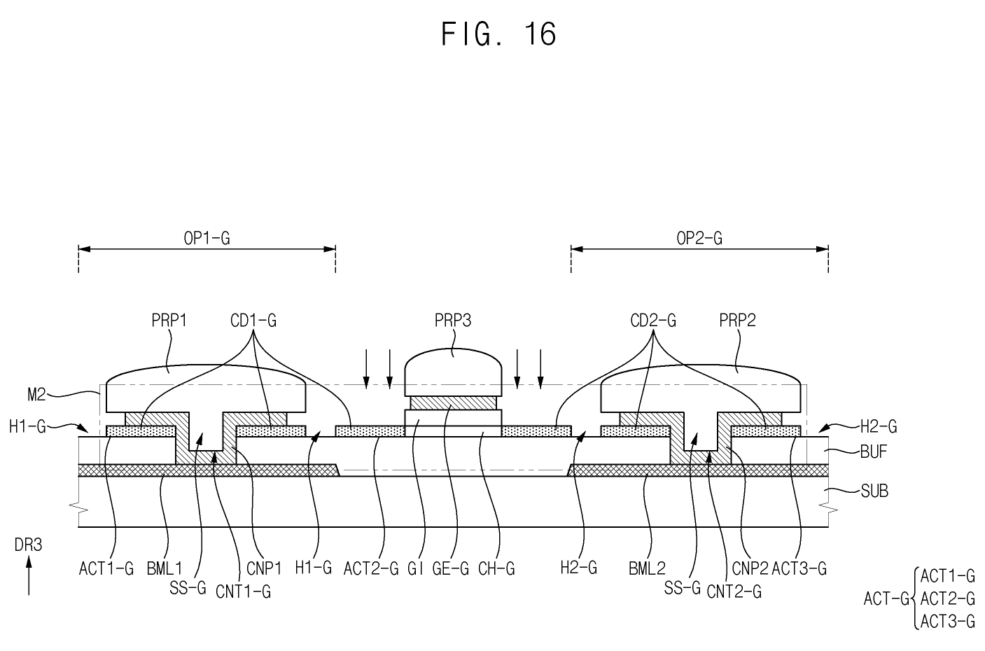

Referring to FIG. 16, through a third etching process, a portion of the gate insulating layer GI may be removed using the first, second, and third photoresist patterns PRP1, PRP2, and PRP3 as masks. For example, the portion of the gate insulating layer GI that do not overlap the first, second, and third photoresist patterns PRP1, PRP2, and PRP3 in the plan view may be removed through the third etching process.

For example, the third etching process may be a dry etching process. However, the embodiments of the present disclosure are not necessarily limited thereto.

During the removal of part of the gate insulating layer GI by the third etching process, hydrogen included in the gate insulating layer GI may flow into the second active pattern ACT2-G. The portion of the second active pattern ACT2-G into which hydrogen is introduced from the gate insulating layer GI has a high carrier concentration due to the introduced hydrogen, thereby becoming conductive, and thus the first conductive region CD1-G and the second conductive region CD2-G. For example, after the third etching process, the areas of the first conductive region CD1-G and the second conductive region CD2-G may be expanded.

Accordingly, the first conductive region CD1-G may be formed to surround the first hole H1-G, and the second conductive region CD2-G may be formed to surround the second hole H2-G.

In this case, a portion of the second active pattern ACT2-G into which hydrogen does not flow may serve as the channel region CH-G. For example, the channel region CH-G may overlap the gate insulating layer GI and the gate electrode GE-G in the plan view.

Accordingly, the buffer transistor M2 including the active layer ACT-G, the gate electrode GE-G, the first connection pattern CNP1, and the second connection pattern CNP2 may be formed in the peripheral area.

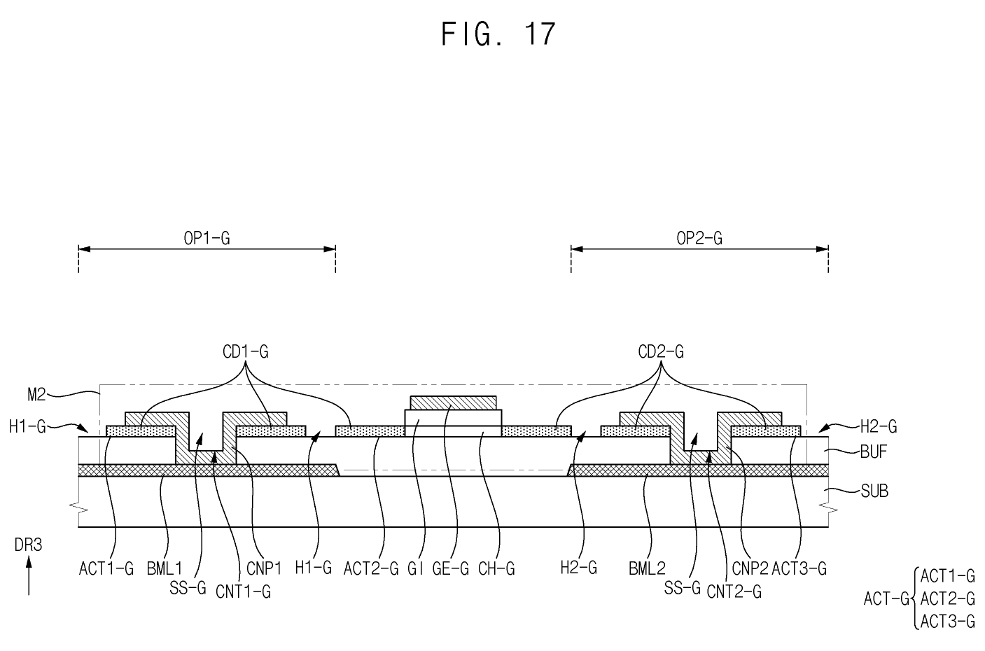

Referring to FIG. 17, after the buffer transistor M2 is formed, the first, second, and third photoresist patterns PRP1, PRP2, and PRP3 may be removed.

Referring again to FIG. 8, the passivation layer PVX may be formed on the gate insulating layer GI, the gate electrode GE-G, the first connection pattern CNP1, and the second connection electrode CNP2. For example, the passivation layer PVX may be formed using an inorganic insulating material.

The via insulating layer VIA may be formed on the passivation layer PVX. For example, the via insulating layer VIA may be formed using an organic insulating material.

Accordingly, the display device DD shown in FIG. 8 may be manufactured.

Thus, the manufacturing method for the display device DD may involve sequentially forming layers and structures on the substrate SUB, including lower metal layers BML1, BML2, a buffer layer BUF, an active layer ACT-G, a gate insulating layer GI, and then defining opening areas OP1-G, OP2-G, contact holes CNT1-G, CNT2-G, and conductive regions CD1-G, CD2-G through controlled etching and hydrogen incorporation. Conductive patterns such as the gate electrode GE-G, first and second connection patterns CNP1, CNP2, and holes H1-G, H2-G are created through photoresist and etching steps, after which a passivation layer PVX and a via insulating layer VIA are deposited to complete the buffer transistor M2 and the overall device structure.

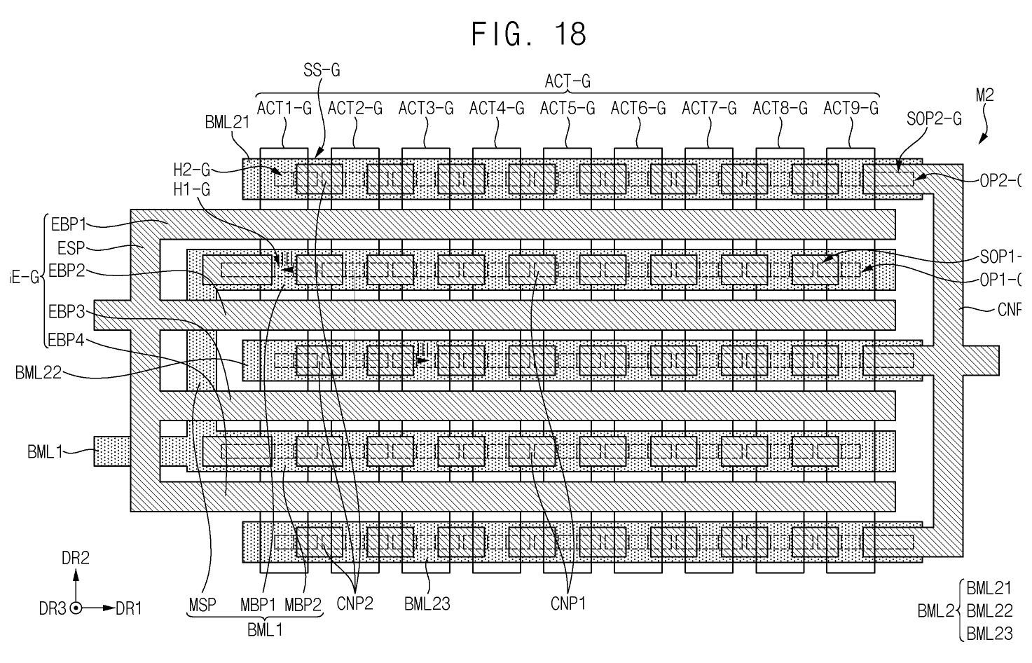

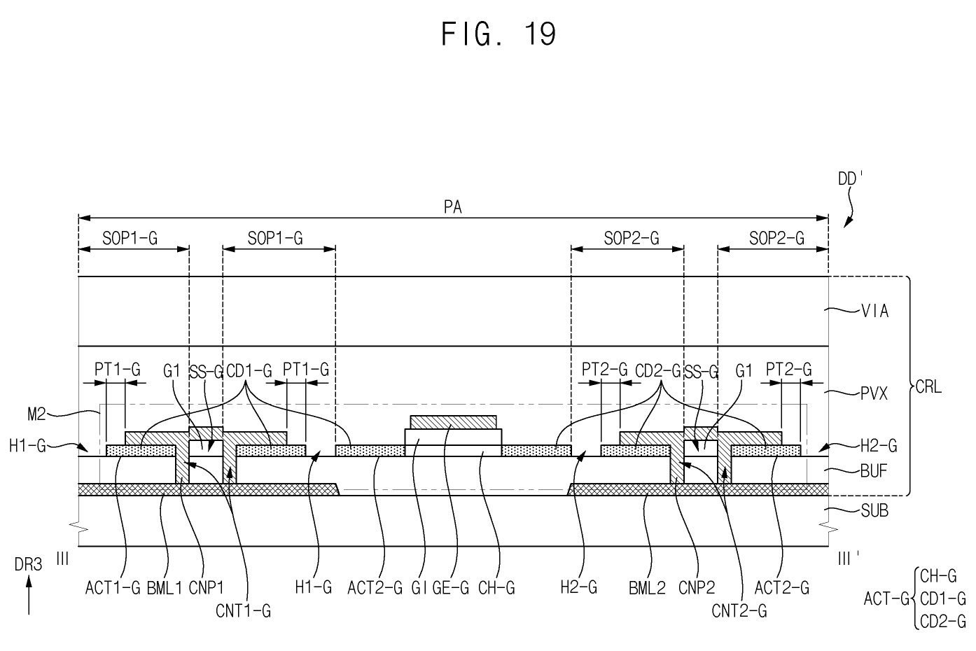

FIG. 18 is a plan view illustrating an example of a buffer transistor of a buffer circuit part included in one stage of FIG. 6. FIG. 19 is a cross-sectional view taken along line III-III’ of FIG. 18. For example, FIG. 19 is a cross-sectional view illustrating a portion of the peripheral area DA.

Referring to FIGS. 18 and 19, a display device DD’ may include the first lower metal layer BML1, the second lower metal layer BML2, the buffer layer BUF, the buffer transistor M2, the gate insulating layer GI, the passivation layer PVX, and the via insulating layer VIA disposed in the peripheral area PA on the substrate SUB. The buffer transistor M2 may include the active layer ACT-G, the gate electrode GE-G, the first connection electrode, the second connection electrode, and the third connection pattern CNP3.

The display device DD’ described with reference to FIGS. 18 and 19 may be substantially the same as or similar to the display device DD described with reference to FIGS. 7 and 8, except for the gate insulating layer GI. Hereinafter, to the extent that an element is not described in detail with respect to this figure, it may be understood that the element is at least similar to a corresponding element that has been described elsewhere within the present disclosure.

In an embodiment, the first lower metal layer BML1 may include the metal stem portion MSP extending in the second direction DR2, and the metal branch portions MBP1 and MBP2 each extending from the metal stem portion MSP in the first direction DR1. The metal branch portions MBP1 and MBP2 may be spaced apart from each other along the second direction DR2.

In an embodiment, the second lower metal layer BML2 may include the lower metal patterns BML21, BML22, and BML23, each extending in the first direction DR1. The lower metal patterns BML21, BML22, and BML23 may be spaced apart from each other along the second direction DR2.

The gate insulating layer GI may be disposed on the active layer ACT-G. In an embodiment, the first opening area OP1-G exposing the first conductive region CD1-G and the first holes H1-G, and the second opening area OP2-G exposing the second conductive region CD2-G and the second holes H2-G may be defined in the gate insulating layer GI.

In an embodiment, the first opening area OP1-G may be divided into a plurality of first sub-opening areas SOP1-G spaced apart from each other along the first direction DR1, and the second opening area OP2-G may be divided into a plurality of second sub-opening areas SOP2-G spaced apart from each other along the first direction DR1. For example, the first opening area OP1-G might not continuously extend along the first direction DR1, and the second opening area OP2-G may also not continuously extend along the first direction DR1.

In an embodiment, one end of each of the first sub-opening areas SOP1-G parallel to the second direction DR2 may overlap the separation space SS-G between two adjacent active patterns among the active patterns ACT1-G, ACT2-G, ACT3-G, ACT4-G, ACT5-G, ACT6-G, ACT7-G, ACT8-G, and ACT9-G in the plan view, and one end of each of the second sub-opening areas SOP2-G parallel to the second direction DR2 may overlap the separation space SS-G in the plan view. However, the embodiments of the present disclosure are not necessarily limited thereto.

In an embodiment, the gate electrode GE-G may include the electrode stem portion ESP extending in the second direction DR2, and the electrode branch portions EBP1, EBP2, EBP3, and EBP4 each extending from the electrode stem portion ESP in the first direction DR1. The electrode branch portions EBP1, EBP2, EBP3, and EBP4 may be spaced apart from each other along the second direction DR2.

In an embodiment, the first connection electrode may include the first connection patterns CNP1 spaced apart from each other along the first direction DR1, and the second connection electrode may include the second connection patterns CNP2 spaced apart from each other along the first direction DR1.

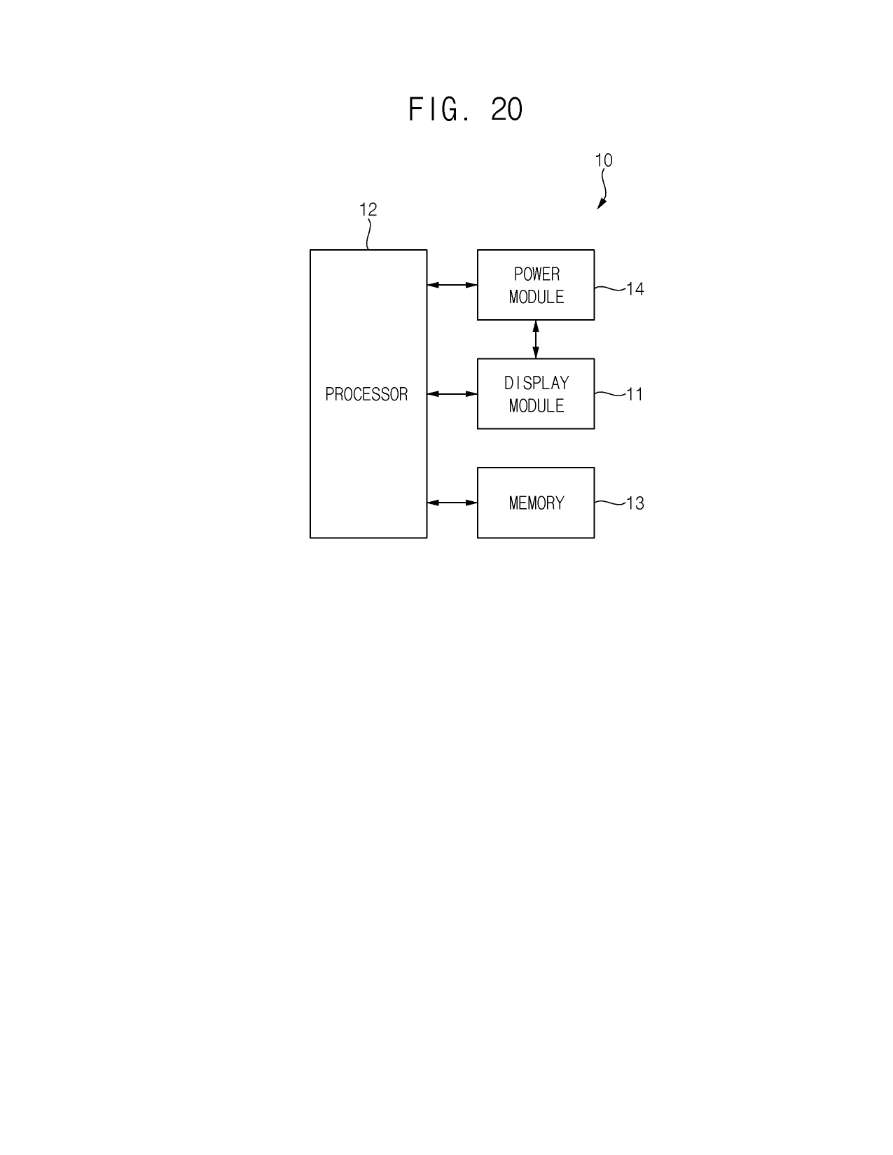

FIG. 20 is a block diagram illustrating an electronic device according to embodiments of the present disclosure.

Referring to FIG. 20, an electronic device 10 according to embodiments of the present disclosure may include a display module 11, a processor 12, a memory 13, and a power module 14.

A display device (e.g., the display device DD of FIGS. 1 to 8 or the display device DD’ of FIGS. 18 and 19) according to embodiments of the present disclosure may be applied to various electronic devices. The electronic device 10 may include the display device described above, and may further include a module or device having additional functions in addition to the display device.

The processor 12 may include at least one of a central processing unit (CPU), an application processor (AP), a graphic processing unit (GPU), a communication processor (CP), and an image signal processor (ISP).

The memory 13 may store data information necessary for the operation of the processor 12 or the display module 11. In case that the processor 12 executes the application stored in the memory 13, an image data signal and/or an input control signal may be transmitted to the display module 11, and the display module 11 may process the received signal and output image information through a display screen.

The power module 14 may include a power supply module which supplies external power, such as a power adapter or a battery device, and a power conversion module which converts the external power supplied by the power supply module to generate power voltage (e.g., the first and second power supply voltages ELVDD and ELVSS of FIG. 6) for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

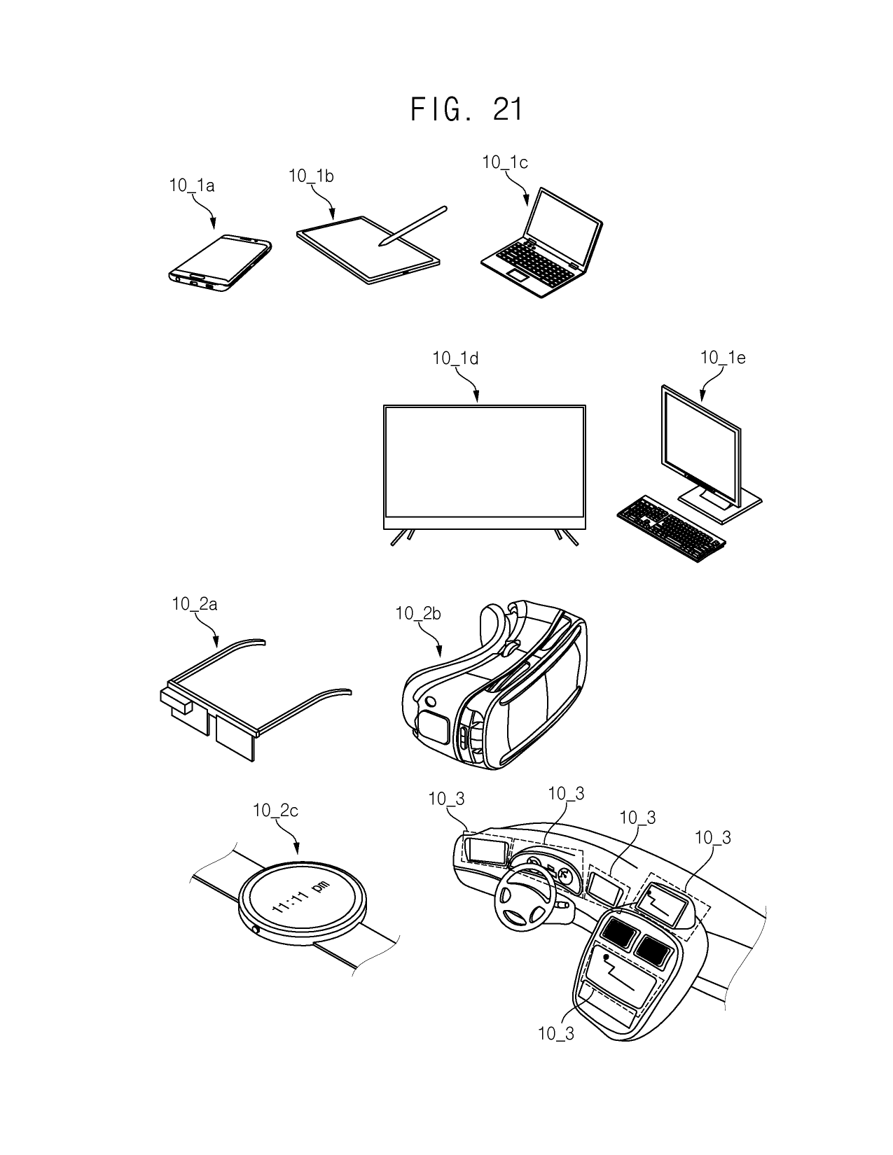

FIG. 21 is a schematic diagram illustrating an electronic device according to various embodiments.

Referring to FIGS. 20 and 21, various electronic devices 10 to which display devices according to the embodiments are applied may include not only image display electronic devices such as a smartphone 10_1a, a tablet computer 100_1b, a laptop/notebook computer 10_1c, a television TV 10_1d, and a computer monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

As described above, while the present disclosure has been explained with reference to embodiments, it will be understood by those of ordinary skill in the art that various modifications and changes can be made thereto without departing from the spirit and scope of the present disclosure.

The present disclosure may be applied to various display device which can be equipped with a display device. For example, the present disclosure may be applied to high-resolution smartphones, mobile phones, smart pads, smart watches, tablet computers, vehicle navigation systems, televisions, computer monitors, and laptop/notebook computers.

What is claimed is:

1. A display device, comprising:
a substrate including a display area including a plurality of pixels and a peripheral area surrounding the display area; and
a gate driver disposed in the peripheral area and configured to provide a gate signal to the plurality of pixels, the gate driver including at least one buffer transistor including:
a first lower metal layer disposed on the substrate;
a second lower metal layer disposed on a same layer as the first lower metal layer;
an active layer disposed on the first and second lower metal layers and including a plurality of active patterns that are spaced apart from each other along a first direction;
a gate electrode disposed on the active layer and overlapping a channel region of the active layer;
a first connection electrode contacting both the first lower metal layer and a first conductive region of the active layer, the first connection electrode including a plurality of first connection patterns that are spaced apart from each other along the first direction; and
a second connection electrode contacting both the second lower metal layer and a second conductive region of the active layer, the second connection electrode including a plurality of second connection patterns that are spaced apart from each other along the first direction.

2. The display device of claim 1, wherein each of the plurality of first connection patterns contacts the first lower metal layer through a separation space between two adjacent active patters among the active patterns, and
wherein each of the plurality of second connection patterns contacts the second lower metal layer through the separation space.

3. The display device of claim 1, wherein a plurality of first holes penetrating a portion of the first conductive region and spaced apart from each other and a plurality of second holes penetrating a portion of the second conductive region and spaced apart from each other are defined in each of the plurality of active patterns, and
wherein in one active pattern among the plurality of active patterns, each of the plurality of first holes and each of the plurality of second holes are alternatively arranged with one another along a second direction intersecting the first direction.

4. The display device of claim 3, wherein each of the first holes are located between the first connection patterns and each of the second holes are located between the second connection patterns.

5. The display device of claim 3, further comprising:
a gate insulating layer disposed between the active layer and the gate electrode, the gate insulating layer including a first opening area exposing the first holes and the first conductive region, and a second opening area exposing the second holes and the second conductive region,
wherein opposite ends of the first opening area, in the first direction, overlap the first connection patterns and opposite ends of the second opening area, in the first direction, overlap the second connection patterns.

6. The display device of claim 5, wherein the first opening area extends continuously in the first direction and the second opening area extends continuously in the first direction.

7. The display device of claim 5, wherein the opposite ends, in the first direction, of the first opening area coincide with opposite ends, in the first direction, of each of the first holes, and
the opposite ends, in the first direction, of the second opening area coincide with opposite ends, in the first direction, of each of the second holes.

8. The display device of claim 5, wherein the first opening area is divided into a plurality of first sub-opening areas that are spaced apart from each other along the first direction, and
wherein the second opening area is divided into a plurality of second sub-opening areas that are spaced apart from each other along the first direction.

9. The display device of claim 8, wherein one end of each of the first sub-opening areas, in a second direction interesting the first direction, overlaps a separation space between two adjacent active patterns among the active patterns, and
wherein one end of each of the second opening areas, in the second direction, overlaps the separation space.

10. The display device of claim 1, wherein the gate electrode includes a plurality of electrode branch portions, each extending along the first direction and spaced apart from each other along a second direction intersecting the first direction, and
wherein the first lower metal layer includes a plurality of metal branch portions each extending along the first direction and spaced apart from each other along the second direction.

11. The display device of claim 10, wherein the second lower metal layer includes a plurality of metal patterns, each extending along the first direction and spaced apart from each other along the second direction,
wherein one of the lower metal patterns is disposed between the metal branch portions, and
wherein each of the electrode branch portions is disposed between one metal branch portion among the metal branch portions and one lower metal pattern adjacent to the one metal branch portion among the lower metal patterns.

12. The display device of claim 11, wherein the first connection patterns contact the metal branch portions, respectively, and the second connection patterns contact the lower metal patterns, respectively.

13. The display device of claim 10, wherein the buffer transistor further includes:
a third connection pattern which contacts one end of the second lower metal layer, the first conductive region, and the second conductive region, and is configured to provide the gate signal.

14. The display device of claim 1, wherein the active layer includes a metal oxide semiconductor.

15. The display device of claim 1, wherein the first connection electrode and the second connection electrode include a same material as the gate electrode.

16. An electronic device, comprising:
a display device including:
a substrate including a display area including a plurality of pixels and a peripheral area surrounding the display area; and
a gate driver disposed in the peripheral area and configured to provide a gate signal to the plurality of pixels, the gate driver including at least one buffer transistor including:
a first lower metal layer disposed on the substrate;
a second lower metal layer disposed on a same layer as the first lower metal layer;
an active layer disposed on the first and second lower metal layers and including a plurality of active patterns that are spaced apart from each other along a first direction;
a gate electrode disposed on the active layer and overlapping a channel region of the active layer;
a first connection electrode contacting both the first lower metal layer and a first conductive region of the active layer, and the first connection electrode including a plurality of first connection patterns that are spaced apart from each other along the first direction; and
a second connection electrode contacting both the second lower metal layer and a second conductive region of the active layer, and the second connection electrode including a plurality of second connection patterns that are spaced apart from each other along the first direction; and
a power module including both a power supply module configured to supply an external power, and a power conversion module configured to convert the external power supplied by the power supply module to generate a power voltage provided to the pixels.

17. The electronic device of claim 16, wherein each of the first connection patterns contacts the first lower metal layer through a separation space between two adjacent active patters among the active patterns, and
wherein each of the second connection patterns contacts the second lower metal layer through the separation space.

18. The electronic device of claim 16, wherein a plurality of first holes penetrating a portion of the first conductive region and spaced apart from each other and a plurality of second holes penetrating a portion of the second conductive region and spaced apart from each other are defined in each of the active patterns,
wherein in one active pattern among the active patterns, the first holes and the second holes are alternatively arranged along a second direction intersecting the first direction, and
wherein each of the first holes are located between the first connection patterns and each of the second holes are located between the second connection patterns.

19. The electronic device of claim 18, wherein the display device further includes:
a gate insulating layer disposed between the active layer and the gate electrode, and in which a first opening area exposing the first holes and the first conductive region, and a second opening area exposing the second holes and the second conductive region are defined,
wherein opposite ends, in the first direction, of the first opening area overlap the first connection patterns and opposite ends, in the first direction, of the second opening area overlap the second connection patterns.

20. The electronic device of claim 19, wherein the opposite ends, in the first direction, of the first opening area coincide with opposite ends, in the first direction, of each of the first holes, and
wherein the opposite ends, in the first direction, of the second opening area coincide with opposite ends, in the first direction, of each of the second holes.
